(19) United States
(12) Patent Application Publication
(10) Pub. No.: US 2025/0132666 A1
(43) Pub. Date: Apr. 24, 2025

(54) HYBRID POWER CONVERTERS, LATERAL DEVICES, VERTICAL DEVICES, MULTIPLE COPPER CLIPS, REPLICA DEVICES

(71) Applicant: Murata Manufacturing Co., Ltd., Kyoto (JP)

(72) Inventors: David GIULIANO, San Diego, CA (US); Kousassi Sebastien KOUASSI, San Diego, CA (US)

(21) Appl. No.: 18/489,574

(22) Filed: Oct. 18, 2023

(51) Int. Cl. H02M 3/07; H01L 23/00; H01L 23/495; H01L 25/065; H01L 27/092; H01L 29/78; H03K 17/687

(52) U.S. Cl. CPC H02M 3/07; H01L 23/49575; H01L 24/16; H01L 24/37; H01L 24/40; H01L 24/48; H01L 24/73; H01L 25/0655; H03K 17/6871; H01L 2224/16245; H01L 2224/37147; H01L 2224/40245; H01L 2224/48245; H01L 2224/73221; H10D 30/65; H10D 30/66; H10D 84/85

(57) ABSTRACT

Disclosed embodiments may include systems, devices, processes, and methods for fabricating and packaging power converters on an integrated circuit. In some embodiments, a power converter device may be processed and packaged using a hybrid (co-packaged) approach. The power converter includes a first integrated circuit die with a plurality of first switches and a plurality of second switches. The power converter further includes a second integrated circuit die including a controller circuit that is electrically coupled to control switching of the plurality of first switches and the plurality of second switches. The power converter may include additional integrated circuit dies coupled to the controller circuit. The plurality of first switches and the plurality of second switches may each include vertical double-diffused metal-oxide semiconductor field effect transistors. The plurality of first switches and the plurality of second switches may each include lateral double-diffused metal-oxide semiconductor field effect transistors.

### TECHNICAL FIELD

The present disclosure generally relates to power converter device structures and to semiconductor device processes and packaging for power converters. More particularly, the present disclosure relates to power converters that include lateral devices, vertical devices, and lateral double-diffused metal-oxide-semiconductor devices that are packaged using a hybrid (co-packaged) approach.

### BACKGROUND

With the advancements in integrated circuit technologies and computing capabilities, there is a commensurate growth in the demand for integrated power conversion, regulation, and its management. Power management circuits of most portable electronic devices and consumer electronics rely on power converters, and more typically DC-DC power converters, to accomplish energy transfer and voltage conversion to a desired voltage level. For example, certain devices may require a power converter that can provide a high power level (greater than 1,000 Watts). Other devices may require a power converter that can provide a low power level (less than 100 Watts). And still other devices may require a power converter that can provide a middle power level (between about 100 Watts and about 1,000 Watts).

### SUMMARY

Embodiments of this disclosure provide a power converter device or apparatus that is co-packaged. One aspect of this disclosure is directed to a power conversion device. The device may include a first integrated circuit die that includes a plurality of first switches, a plurality of second switches, a plurality of first capacitors, and a plurality of second capacitors. The device may also include a second integrated circuit die that includes a controller circuit coupled to the first integrated circuit die that controls the switching of the plurality of first switches and the plurality of second switches.

For example, embodiments of the present disclosure may include an integrated circuit package including: a first integrated circuit die electrically coupled to a lead frame; wherein the first integrated circuit die includes a plurality of first switches and a plurality of second switches; wherein the plurality of first switches and the plurality of second switches are interconnected with a plurality of first capacitors to form a first switched capacitor circuit, wherein the first switched capacitor circuit is configured to transition between at least two states in response to switching of the plurality of first switches and the plurality of second switches; and a second integrated circuit die; wherein the second integrated circuit die includes a controller circuit that is electrically coupled to control switching of the plurality of first switches and the plurality of second switches; and a third integrated circuit die electrically coupled to the lead frame; wherein the third integrated circuit die includes a plurality of third switches and a plurality of fourth switches; wherein the plurality of third switches and the plurality of fourth switches are interconnected with a plurality of second capacitors to form a second switched capacitor circuit, wherein the second switched capacitor circuit is configured to transition between at least two states in response to switching of the plurality of third switches and the plurality of fourth switches; and wherein the controller circuit is electrically coupled to control switching of the plurality of third switches and the plurality of fourth switches; wherein the first integrated circuit die, the second integrated circuit die, and the third integrated circuit die are co-packaged; and wherein at least one of the plurality of first switches and the plurality of second switches has a different current rating than at least one of the plurality of third switches and the plurality of fourth switches.

Embodiments of the present disclosure may include a vertical double-diffused metal-oxide-semiconductor field effect transistor comprising a drift region, a source region, a drain region, and a gate; wherein the vertical double-diffused metal-oxide-semiconductor field effect transistor is isolated by an isolation trench formed around the vertical double-diffused metal-oxide-semiconductor field effect transistor; wherein the isolation trench is filled with an electrically isolating material; and wherein the isolation trench goes through the bottom of the drain.

Embodiments of the present disclosure may include a lateral double-diffused metal-oxide-semiconductor field effect transistor comprising a drift region, a source region, a drain region, a gate, and a substrate; wherein the lateral double-diffused metal-oxide-semiconductor field effect transistor has a through-silicon via for formation of an electrical connection to the drain from the bottom surface of the lateral double-diffused metal-oxide-semiconductor field effect transistor.

Additional features and advantages of the disclosed embodiments will be set forth in part in the following description, and in part will be apparent from the description, or may be learned by practice of the embodiments. The features and advantages of the disclosed embodiments may be realized and attained by the elements and combinations set forth in the claims.

### BRIEF DESCRIPTION OF THE DRAWINGS

Embodiments and various aspects of the present disclosure are illustrated in the following detailed description and the accompanying figures. It is noted that, in accordance with standard practice in the industry, various features are not drawn to scale. In fact, the dimensions of the various features may be arbitrarily increased or reduced for clarity of discussion.

FIG. 1 is a schematic illustration of an exemplary power converter, including a switched capacitor circuit and controller circuit, in accordance with embodiments of the present disclosure.

FIG. 2 is a schematic illustration of a monolithic power converter approach.

FIG. 3 is a schematic illustration of a discrete power converter approach.

FIG. 4 is a graphical representation of the cost of using the monolithic approach at various power levels, the cost of using the discrete approach at various power levels, and the cost of using the hybrid (co-packaged) approach at various power levels.

FIG. 5 is a graphical representation of the cost of packaging and the cost of silicon for each of the monolithic, hybrid, and discrete approaches, respectively, at a given power level, in accordance with embodiments of the present disclosure.

FIG. 6 is a schematic illustration of a schematic plan view of a power converter device using the hybrid (co-packaged) approach, in accordance with embodiments of the present disclosure.

FIG. 7 is a schematic illustration of a cross-section view of a power converter device using the hybrid (co-packaged) approach, in accordance with embodiments of the present disclosure.

FIG. 8A shows a schematic illustration of a cross-section view of an integrated circuit die implementing three isolated vertical double-diffused metal-oxide-semiconductor (VDMOS) field effect transistor devices shown in FIG. 15, in accordance with embodiments of the present disclosure.

FIG. 8B shows a schematic illustration of a plan view of an integrated circuit die implementing three isolated vertical double-diffused metal-oxide-semiconductor (VDMOS) field effect transistor devices shown in FIG. 15, in accordance with embodiments of the present disclosure.

FIG. 9 is a plan view of an integrated circuit die implementing replica field effect transistors, in accordance with embodiments of the present disclosure.

FIG. 10 is a schematic illustration of a cross-section view of an exemplary lateral double-diffused metal-oxide-semiconductors (LDMOS) field effect transistor device, in accordance with embodiments of the present disclosure.

FIG. 11 is a schematic illustration of a cross-section view of an exemplary lateral double-diffused metal-oxide-semiconductors (LDMOS) field effect transistor device that is converted into a vertical device by etching a through-silicon via from the bottom surface of the device to the drain, in accordance with embodiments of the present disclosure.

FIG. 12A is a flow chart diagram of the process for manufacturing the lateral double-diffused metal-oxide-semiconductor (LDMOS) described in FIG. 11, in accordance with embodiments of the present disclosure.

FIG. 12B is a cross-sectional schematic diagram of the lateral double-diffused metal-oxide semiconductor (LDMOS) described in FIG. 11 during various steps in the STL manufacturing process outlined in FIG. 12A, in accordance with embodiments of the present disclosure.

FIGS. 13A, 13B, 13C, and 13D show a process for manufacturing the lateral double-diffused metal-oxide-semiconductor (LDMOS) described in FIG. 11, in accordance with embodiments of the present disclosure

FIG. 14 is a schematic illustration of a cross-section view of two isolated lateral double-diffused metal-oxide-semiconductors (LDMOS) field effect transistor devices, in accordance with embodiment of the present disclosure.

FIG. 15 is a schematic illustration of a cross-section view of two exemplary vertical double-diffused metal-oxide-semiconductor (VDMOS) field effect transistor device where the drain regions are connected to one another, in accordance with embodiments of the present disclosure.

FIG. 16 is a schematic illustration of a cross-section view of an exemplary isolated vertical double-diffused metal-oxide-semiconductor (VDMOS) field effect transistor device, in accordance with embodiments of the present disclosure.

FIG. 17 is a schematic illustration of a cross-section view of two isolated vertical double-diffused metal-oxide-semiconductor (VDMOS) field effect transistor devices, in accordance with embodiments of the present disclosure.

### DETAILED DESCRIPTION

The following disclosure provides many different exemplary embodiments, or examples, for implementing different features of the provided subject matter. Specific simplified examples of components and arrangements are described below to explain the present disclosure. These are, of course, examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, the term “coupled” may also be termed as “electrically coupled”, and the term “connected” may be termed as “electrically connected”. “Coupled” and “connected” may also be used to indicate that two or more elements cooperate or interact with each other or maintain an electrical continuity between each other.

Semiconductor packages are widely used for protecting an integrated circuit (IC) chip and providing an electrical interface to external circuitry. With the increasing demand for smaller device sizes and higher power densities, packages for power modules are designed to be more compact with increased circuit density. In power devices, power converters, such as charge pump converters, include switches forming a switch network and one or more capacitors to achieve the power conversion and regulate an output voltage or current by switching energy storage elements (e.g., capacitors and/or inductors) between different electrical configurations. These devices are processed using one of two main types of power processes.

The first process uses a low mask count and creates a power device with discrete field effect transistors. The field effect transistors can be the vertical double-diffused metal-oxide-semiconductor (VDMOS) field effect transistor devices or the lateral double-diffused metal-oxide-semiconductor (LDMOS) field effect transistor devices as described in the present disclosure. This is known as the monolithic approach. In the monolithic approach, the field effect transistors are not electrically isolated and the power converter is only rated for a single-voltage rating.

The second process uses a high mask count bipolar/CMOS/DMOS process and results in isolated field effect transistors. The field effect transistors can be the vertical double-diffused metal-oxide-semiconductor (VDMOS) field effect transistor devices or the lateral double-diffused metal-oxide-semiconductor (LDMOS) field effect transistor devices as described in the present disclosure. This is known as the discrete approach. In the discrete approach, the field effect transistors are isolated and the power converter can be rated for multiple-voltage ratings.

There are distinct tradeoffs for each of these approaches. For example, in devices implementing the monolithic approach, the field effect transistors are not isolated and therefore only have a single-voltage rating. The discrete approach, meanwhile, can be more expensive as it uses a high mask count.

Ideally, there would exist a process that has a low mask count that allows for integration field effect transistor devices with multiple different power ratings on a single wafer. This can be achieved by using a process that requires a high number of masks and removing the un-used masks during the process. But, this still results in a process with a higher number of masks than the low mask count process described above.

There also exists an additional challenge because changing the voltage rating of, for example, a vertical field effect transistor device, requires changing particular device parameters. For example, changing the doping amount and thickness of the epitaxial wafer can change the voltage rating. As another example, changing the implantation doping amount can change the voltage rating of a device. Because of the difficultly of changing the voltage rating of a given device, it would be suboptimal to integrate vertical field effect transistors with different voltage ratings on a single substrate. Furthermore, isolating these devices presents another problem because the isolation wells/regions need to be as deep as the thickness of the substrate.

In general, high efficiency power converters (e.g., charge pumps, multi-level converter, series-cap buck) use power switches with different voltage ratings.

The disclosed embodiments address the need for a device with reduced packaging cost and the ability to use field effect transistors with different voltage ratings by providing co-packaging novel lateral double-diffused metal-oxide-semiconductor (LDMOS) field effect transistor devices as described in the present disclosure with a power converter controller. This is called the hybrid (co-packaged) approach. The hybrid (co-packaged) approach allows for a device with a small area footprint and a higher efficiency when compared to power converters implementing the discrete approach. Another benefit to the hybrid (co-packaged) approach is that it implements an integrated controller. Using an integrated controller can increase the efficiency of the total power converter by minimizing parasitics between the power switches and the controller.

Implementing the lateral double-diffused metal-oxide-semiconductor (LDMOS) field effect transistor devices described in the present disclosure on a single wafer allows for devices with different voltage ratings. The voltage ratings can be adjusted by adjusting the length of the drift region and adjusting the length of the channel, without incurring a change in mask count. By implementing this approach, the overall cost of manufacturing can be reduced relative to other approaches that allow for devices with different voltage ratings.

The disclosed embodiments provide examples of lateral double-diffused metal-oxide-semiconductor (LDMOS) field effect transistor device structures and methods to fabricate these structures for use in hybrid (co-packaged) power converters described in the present disclosure.

Accordingly, designing a power converter process, device, and packaging system that is able to have a low mask count semiconductor package while still enabling different voltage ratings and isolation of the devices is difficult given the nature of the two power converter processes. Thus, there is a need for a power converter process, device, and packaging system, such as the one described above, that enables a low-cost, low mask semiconductor package where the individual field effect transistors are isolated and are able to have different voltage ratings.

Various non-limiting embodiments of the present disclosure will be described with respect to embodiments in a specific context, namely a power converter that is package using a hybrid (co-packaged) approach. As used in this disclosure, the term “voltage regulator” refers to a component of the power supply unit (PSU) configured to convert an input voltage to a stable output voltage. While most voltage regulators may be used for DC-DC power conversion, some voltage regulators may be used for AC-DC or AC-AC power conversion as well. A linear voltage regulator may be configured to output a lower, stable voltage signal from a higher voltage signal. In some cases, a linear voltage regulator may utilize an input and an output capacitor, or an active pass device, such as a bipolar junction transistor (BJT) or a metal-oxide semiconductor field effect transistor (MOSFET), to regulate the voltage. A switching voltage regulator, however, may be configured as a Step-Down (buck converter), a Step-Up (Boost converter), or a Buck-Boost Converter, with the help of additional external components, such as inductors, capacitors, FETs, or feedback resistors.

A voltage regulator may serve as a power converter. The concepts in the disclosure may apply to voltage regulators or power converters. Power converters which convert a higher input voltage power source to a lower output voltage level may be referred to as step-down or buck converters, because the converter is “bucking” the input voltage. Power converters which convert a lower input voltage power source to a higher output voltage level may be referred to as step-up or boost converters, because the converter is “boosting” the input voltage. In addition, some power converters, commonly known as “buck-boost converters,” may be configured to convert the input voltage power source to the output voltage with a wide range, in which the output voltage may be either higher than or lower than the input voltage. In various embodiments of the present disclosure, a power converter may be bi-directional, being either a step-up or a step-down converter depending on how a power source is connected to the converter. In some embodiments, an AC-DC power converter can be built up from a DC-DC power converter by, for example, first rectifying an AC input voltage to a DC voltage and then applying the DC voltage to a DC-DC power converter.

The inventors here have recognized, however, that existing processes and packaging solutions for voltage regulators and/or power converters may present distinct tradeoffs. For example, when the switches (field effect transistors) are implemented on the same integrated circuit die as the controller, the switches may not be isolated and only have one power rating. As another example, when the switches (field effect transistors) are implemented on separate integrated circuit dies, a high mask count process may be used, driving up cost significantly as you add more switches (field effect transistors). Certain disclosed embodiments may address these and other challenges.

Various embodiments of the present disclosure address these issues by processing and packaging voltage regulators using a hybrid (co-packaged) approach. In the hybrid (co-packaged) approach, the switches (field effect transistors) are implemented on one integrated circuit die while the controller is implemented on another integrated circuit die. The switch integrated circuit die is preferably processed using the first process described above, which is a low mask count process that results in discrete field effect transistors.

Voltage regulators and power converters processed and packaged using a hybrid (co-packaged) approach also cost less to process and manufacture for mid power (greater than 100 Watts, less than 1,000 Watts) applications. For example, for mid power applications the packaging cost is less for the hybrid (co-packaged) approach than the discrete approach and the overall silicon (Si) cost is less the monolithic approach.

In some embodiments utilizing the hybrid (co-packaged) approach, the hybrid power converters can have a single field effect transistor (FET) die and a single controller die. In still other embodiments hybrid power converters can have multiple FET dies and a single controller die.

The hybrid power converters can be packaged in a number of ways. For example, the different dies can be wire bonded to the printed circuit board (PCB) or packaged as a flip-chip on a lead frame. In some embodiments, the hybrid power converters can be coupled to one another via metal clips.

In some embodiments, the hybrid power converters can have FET dies that implement replica field effect transistors. The replica devices may be used to sense current in the main field effect transistor (FET) device and are typically proportional in size to the main field effect transistor (FET) device.

Hybrid power converters can be implemented using many different types of FET devices, including the vertical double-diffused metal-oxide-semiconductor (VDMOS) field effect transistor devices and lateral double-diffused metal-oxide-semiconductor (LDMOS) field effect transistor device devices described in the present disclosure.

In various embodiments of the present disclosure, devices, processes, systems, and methods for processing and packaging voltage regulators or power converters using a hybrid (co-packaged) approach may be disclosed. The disclosed hybrid (co-packaged) approach can provide a low cost solution for mid power level applications while providing an isolated device with multiple voltage ratings. The hybrid process and packaging approach for voltage converters or power converters may be desirable in applications including, but not limited to, portable electronic devices such as tablets, cell phones, or hand-held computers, and IoT (Internet of Things) devices.

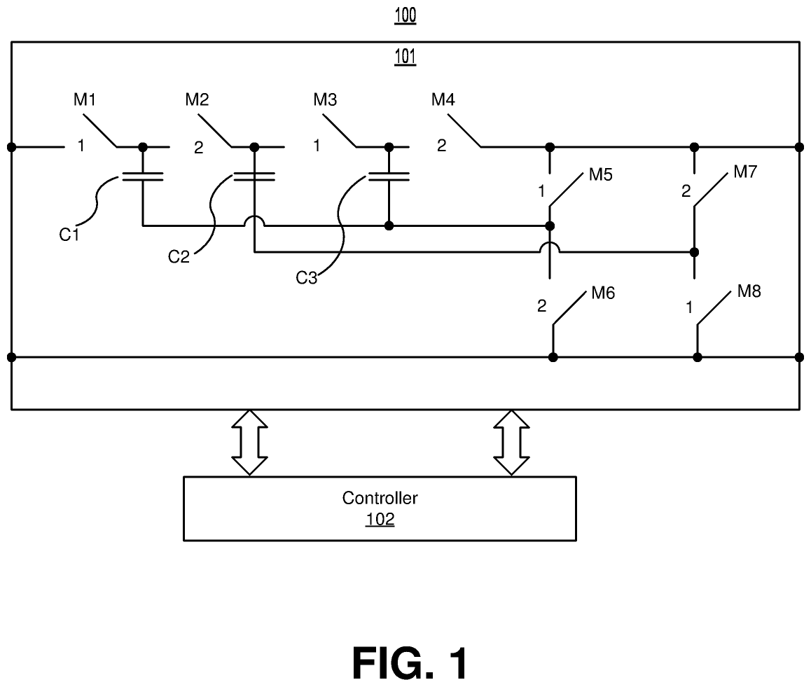

Reference is now made to FIG. 1. FIG. 1 is a schematic illustration of an exemplary power converter, including an exemplary first switched capacitor circuit 101 in integrated circuit package 100, in accordance with some embodiments of the present disclosure. As shown in FIG. 1, the switched capacitor circuit 101 may be implemented on a first integrated circuit die. The first switched capacitor circuit 101 may be a two-phase switched-capacitor power converter including a first plurality of switches M1, M2, M3, and M4, and a second plurality of switches M5, M6, M7, and M8, and a plurality of first capacitors C1, C2, and C3, but the present disclosure is not limited thereto. In still other embodiments, the switched capacitor circuit 101 may be single phase or multiple phase and may be designed to have more or less switches and/or capacitors based on a desired voltage conversion ratio.

In the example shown in FIG. 1, the switched capacitor circuit 101 may be configured to receive energy from an input voltage source at the high input voltage and deliver that energy to an output load at the low output voltage. Controller circuit 102 may be implemented on a second integrated circuit die and operate in response to one or more I/O signals, which may be digital communication signals, to control the switched capacitor circuit 101. The controller circuit 102 may include one or more complementary metal-oxide-semiconductor field effect transistors (MOSFETs).

The controller circuit 102 may be coupled to the switched capacitor circuit 101 and may be configured to open and close switches M1, M2, M3, M4, M5, M6, M7, and M8 to achieve the desired power conversion. In some embodiments, a 4:1 transformation ratio may be obtained. In some other embodiments, different transformation ratios (e.g., a 2:1 transformation ratio or a 3:1 transformation ratio) may be obtained by using a different number of capacitors and a different number of switches.

During operation, switches M1, M3, M5, and M8, which are marked as group 1 in FIG. 1, and switches M2, M4, M6, and M7, which are marked as group 2 in FIG. 1, may be in complementary states. For example, in a first state, the switches M1, M3, M5, and M8 may be closed and the switches M2, M4, M6, and M7 may be open, in response to the commands from the controller circuit 102. In a second switch state following the first switch state, the switches M2, M4, M6, and M7 may be closed and the switches M1, M3, M5, and M8 may be open, in response to the commands from the controller circuit 102. Furthermore, a dead-time interval may exist between the first state and the second state. During the dead-time interval, all the switches are open, which ensures a clean transition between the two states. It should be understood that the present disclosure is not limited to such a ratio or type of conversion circuit. In various embodiments, a step-down or a step-up configuration may be applied to all possible charge pump ratios.

In some embodiments, switched capacitor circuit 101 may be a first switched capacitor circuit having a power rating of between about 100 Watts and about 1,000 Watts. The integrated circuit package 100 may be implemented using a surface-mounted package, a flat no-lead package, a quad flat no-lead package, or any other suitable packaging implementation.

In some embodiments, a third integrated circuit die including a third and fourth plurality of switches and a plurality of second capacitors that make up a second switched capacitor circuit may be coupled to the controller circuit 102. The second switched capacitor circuit may be coupled in parallel. The controller circuit 102 may control the switching of the third and fourth plurality of switches in the same manner it controls the switching of the first and second plurality of switches. In this embodiment, the first, second, third, and fourth plurality of switches may all have the same current rating or may all have different current ratings. Similarly, at least one of the plurality of first switches and the plurality of second switches may have a different current rating than at least one of the plurality of third switches and the plurality of fourth switches.

In other embodiments, a fourth integrated circuit die including a fifth and sixth plurality of switches and a plurality of third capacitors that make up a third switched capacitor circuit may be coupled to the controller circuit 102. The third switched capacitor circuit may be coupled in parallel. The controller circuit 102 may control the switching of the fifth and sixth plurality of switches in the same manner it controls the switching of the first and second plurality of switches. In this embodiment, the first, second, third, fourth, fifth, and sixth plurality of switches may all have the same current rating or may all have different current ratings. Similarly, at least one of the plurality of first switches and the plurality of second switches may have a different current rating than at least one of the plurality of third switches and the plurality of fourth switches.

The controller circuit 102 may be able to control the switching of switches having a current rating between about 10 amps and about 40 amps. The controller circuit 102 may also be configured to control the switching of switches having a current rating less than 10 amps and greater than 40 amps, depending on the desired application.

The first, second, and third integrated circuit die may be electrically coupled to a lead frame using wire-bonding or flip-chip bonding. The first, second, and third integrated circuit die may use metal clips to couple the source and drain terminals of the first, second, third, fourth, fifth, and sixth plurality of switches. The metal clips may be copper clips.

It is understood that switched capacitor circuits, like the one illustrated in FIG. 1, can be a more expensive implementation for power converters depending on the power level of the application and the desired conversion ratio. Because of these cost considerations, power converter designers generally rely upon two distinct types of switch capacitor circuit implementations: monolithic circuit implementations and fully discrete circuit implementations. These circuit implementations have certain benefits and drawbacks depending on the power levels of the application and are more or less costly depending on the desired power level.

For the purposes of this disclosure, a low power level is a power level that is less than or equal to 100 Watts, a mid power level is a power level that is at greater than 100 Watts but less than 1,000 Watts, and a high power level is a power level that is greater than 1,000 Watts. These power levels and ranges are meant to be exemplary and are not limiting.

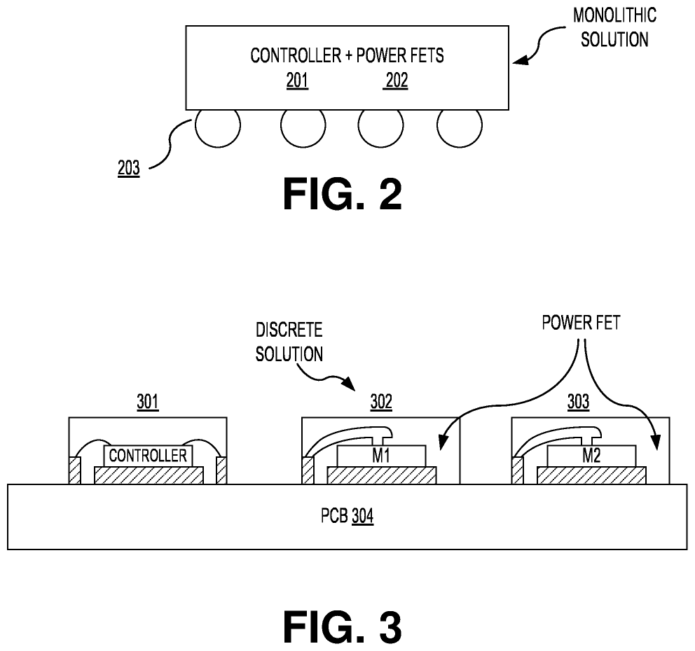

Reference is now made to FIG. 2, which is a schematic illustration of a monolithic power converter implementation (excluding the passive components). As illustrated in FIG. 2, the monolithic power converter implementation is an implementation that includes both the controller 201 and the switched capacitor circuit, made up of individual power field effect transistors (FETs) 202, on a single die. The monolithic power converter implementation can use bumps 203 and be packaged as a flip-chip on a lead frame, as shown in FIG. 2. Monolithic power converter implementations typically use lateral double-diffused metal-oxide-semiconductor (LDMOS) field effect transistors (FETs).

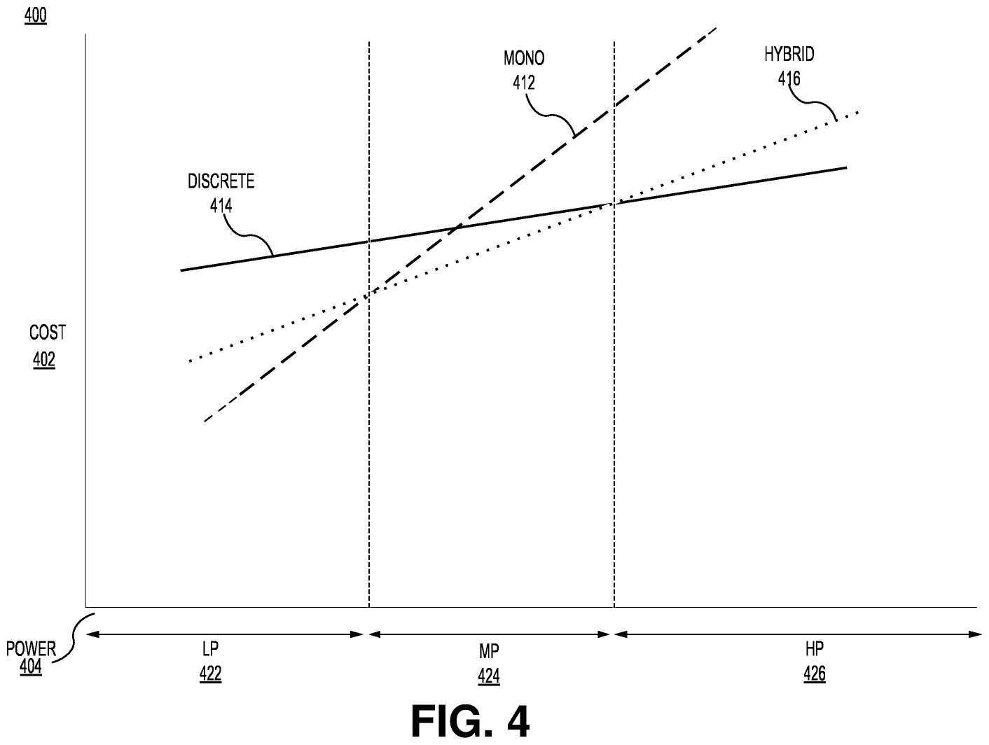

Reference is now made to FIG. 3, which is a schematic illustration of a discrete power converter implementation. As illustrated in FIG. 3, the discrete power converter implementation is an implementation that has separate integrated circuit dies for each of power field effect transistor 302 and power field effect transistor 303 and a separate integrated circuit die for the controller 301. Each of the individual integrated circuit dies are connected to the printed circuit board (PCB) 304, as shown in FIG. 3. Fully discrete power converters have external vertical double-diffused metal-oxide-semiconductor (VDMOS) field effect transistors (FETs) and external controller dies that are packaged separately.

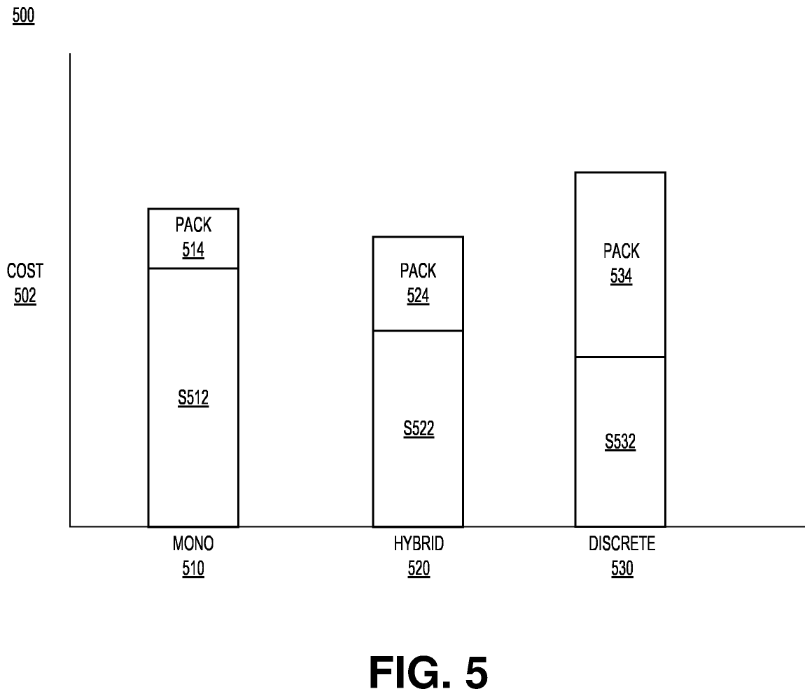

Reference is now made to FIG. 4, which is a graphical representation 400 of the cost 402 of using the monolithic approach 412 at various power levels, the cost of using the discrete approach 414 at various power levels, and the cost of using the hybrid (co-packaged) approach 416 at various power levels. The relative cost of these implementations depends on the desired power level 404. For example, as shown in FIG. 4, at a low power level 422 the monolithic approach 412 is the least expensive and at a high power level 426 the monolithic approach 412 is the most expensive. As another example, as shown in FIG. 4, at a low power level 422, the discrete implementation 414 is the most expensive and at a high power level 426 the discrete implementation 414 is the least expensive. Meanwhile, the hybrid (co-packaged) approach 416, which is described below, is the least expensive at the mid power level 424. Hybrid power converters (also known as co-packaged power converters) have a lateral double-diffused metal-oxide-semiconductor (LDMOS) field effect transistor (FET) die and a controller die that are packaged together.

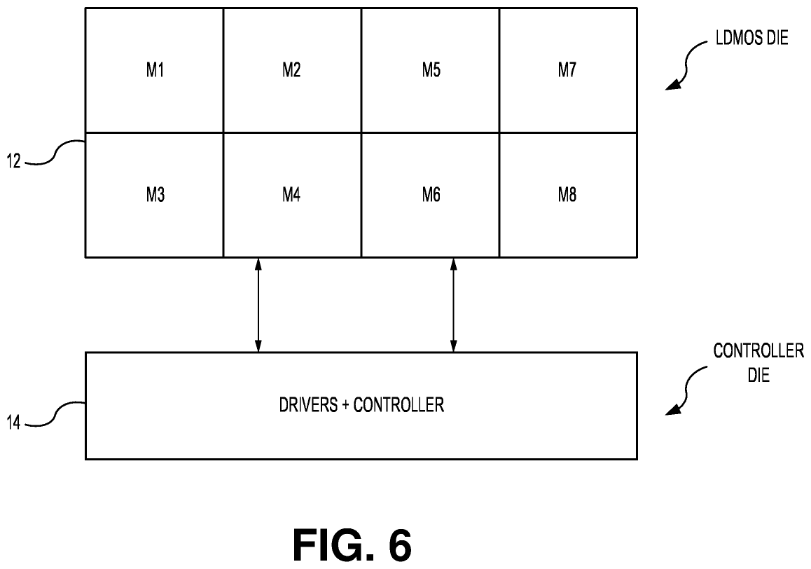

Reference is now made to FIG. 5, which is a graphical representation 500 of the cost 502 (the cost of packaging and the cost of silicon for each of the monolithic, hybrid, and discrete approaches, respectively) at a given power level, in accordance with embodiments of the present disclosure. As shown in FIG. 5, which shows the relative cost of silicon (Si) and packaging (PACK) for each of the monolithic, hybrid, and discrete implementations at a mid power level, silicon costs S512 of the monolithic approach 510 is more expensive than silicon costs S532 and S522 of the discrete 530 and hybrid 520 approaches. This is in part because there is a larger silicon area needed to create the devices in a monolithic approach 510 because the monolithic implementation implements a lateral double-diffused metal-oxide-semiconductor (LDMOS) field effect transistor (FET) die that carries current laterally rather than vertically, thereby driving up the cost of silicon. In the monolithic approach 510, however, packaging costs 514 are relatively low compared to the packaging costs 534 of the discrete approach 530 because a single integrated circuit die is packaged.

As shown in FIG. 5, the discrete approach 530 may overall be more expensive in part due to high packaging costs 534. This is because there are multiple field effect transistor (FET) dies and a controller die that are all packaged separately.

As shown in FIG. 5, in the hybrid (co-packaged) approach 520, the increase in cost caused by using lateral double-diffused metal-oxide-semiconductor (LDMOS) field effect transistors (FETs) dies may be offset by the decrease in packaging costs 524 because the lateral double-diffused metal-oxide-semiconductor (LDMOS) field effect transistor (FET) die and controller die are packaged together.

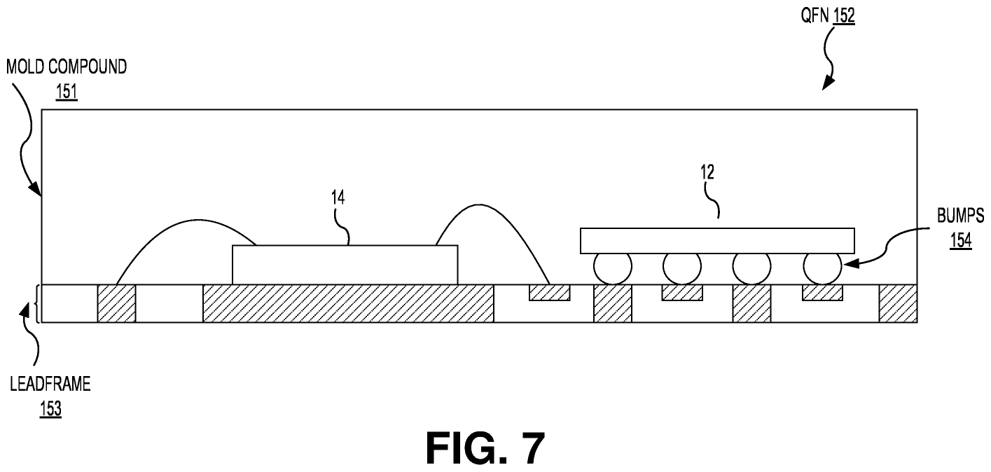

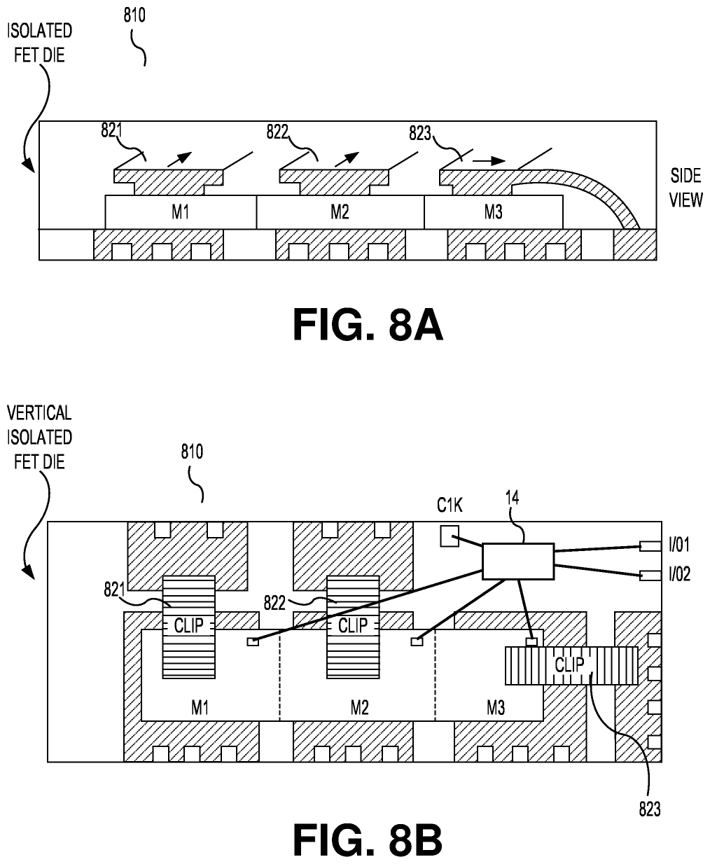

Reference is now made to FIG. 6 and FIG. 7, which are schematic illustrations of an exemplary power converter utilizing the hybrid implementation, in accordance with embodiments of the present disclosure. FIG. 6 shows a schematic illustration of a schematic plan view of a power converter device using the hybrid (co-packaged) approach, in accordance with embodiments of the present disclosure. As shown in FIG. 6, the hybrid (co-packaged) approach implements a single lateral double-diffused metal-oxide-semiconductor (LDMOS) field effect transistor (FET) die including multiple lateral double-diffused metal-oxide-semiconductor (LDMOS) field effect transistor (FET) switches M1-M8 and a single controller die 14. The hybrid implementation described herein can also utilize the vertical double-diffused metal-oxide-semiconductor (VDMOS) field effect transistor (FET) die devices described in the present disclosure.

In power converters using the hybrid (co-packaged) approach, the controller die 14 can be packaged using wire-bonding and the lateral double-diffused metal-oxide-semiconductor (LDMOS) field effect transistor (FET) die 12 can be packaged as a flip-chip component that is attached to a lead-frame. The lateral double-diffused metal-oxide-semiconductor (LDMOS) field effect transistor (FET) die 12 can also be packaged utilizing metal clips to connect individual field effect transistors (FETs) to one another.

FIG. 7 shows one such implementation (e.g., quad-flat no-leads (QFN) 152). FIG. 7 is a schematic illustration of a cross-section view of a power converter device using the hybrid (co-packaged) approach, in accordance with embodiments of the present disclosure. As shown in FIG. 7, the controller die 14 may be packaged using wire-bonding and the lateral double-diffused metal-oxide-semiconductor (LDMOS) field effect transistor (FET) die 12 may be packaged as a flip-chip component attached to the lead-frame using bumps 154 and a mold compound 151. An advantage to wire-bonding the controller die 14 is that it reduces the overall area of the controller by reducing the distance between the pins. For example, the distance between pins in a wire-bond connection can range from between 10 to 20 microns apart, whereas the distance between pins in a leadframe 153 can be up to and more than 400 microns.

An additional advantage to the hybrid (co-packaged) approach is that the hybrid (co-packaged) approach is scalable. This is because there can be multiple field effect transistor (FET) dies implemented in a power converter implementing the hybrid (co-packaged) approach. As an example, a power converter could implement a single lateral double-diffused metal-oxide-semiconductor (LDMOS) field effect transistor (FET) die 12 with multiple lateral double-diffused metal-oxide-semiconductor (LDMOS) field effect transistors (FETs) rated at 10 amps. The controller die 14 can be designed to handle field effect transistors with current ratings between 10 and 40 amps. In the hybrid (co-packaged) approach, additional lateral double-diffused metal-oxide-semiconductor (LDMOS) field effect transistor (FET) die may be added and connected in parallel to increase the overall power rating of the device. Furthermore, implementing the lateral double-diffused metal-oxide-semiconductor (LDMOS) field effect transistor (FET) dies on two separate pieces of silicon enables the device to have different power levels that are scalable.

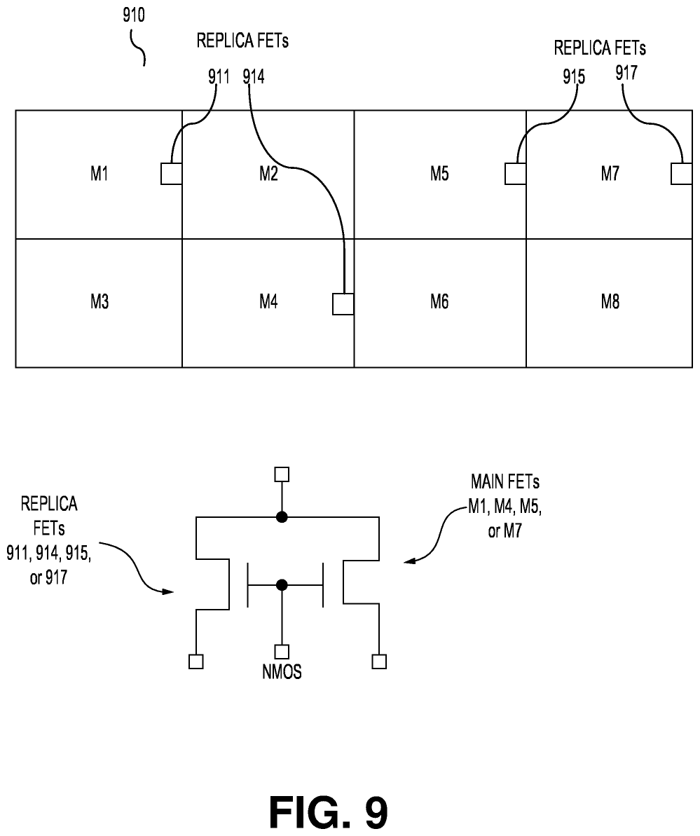

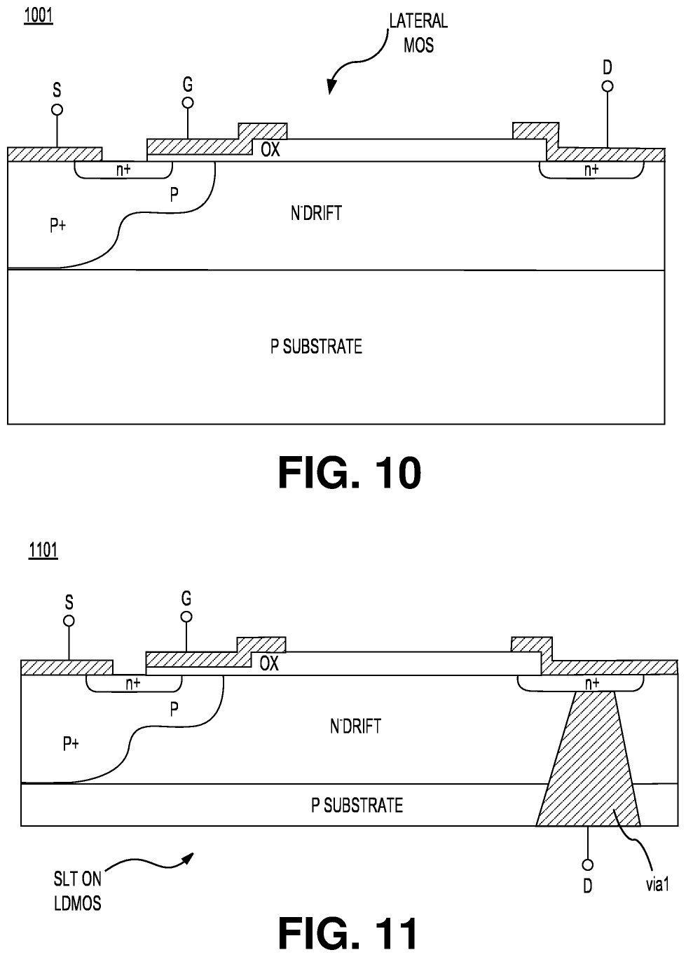

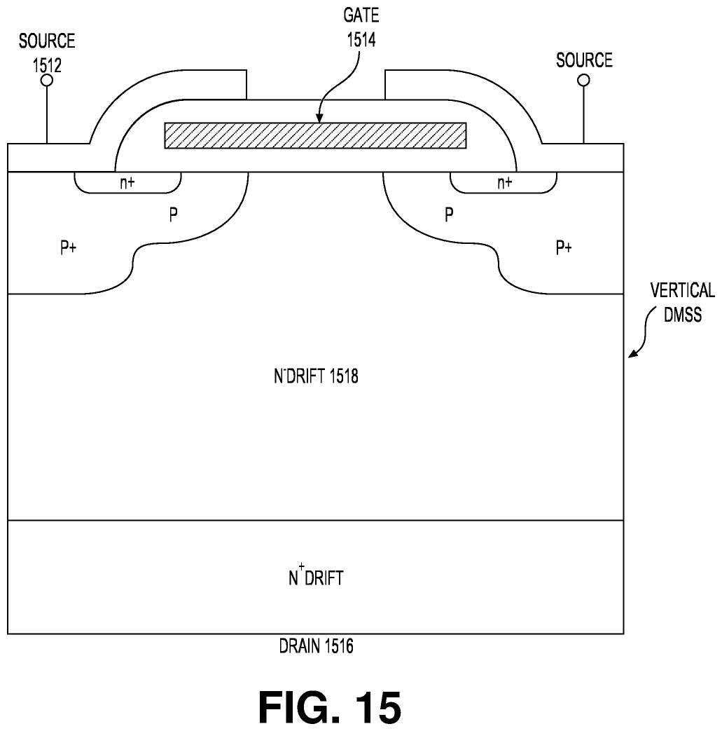

Reference is now made to FIG. 8A, which shows a schematic illustration of a cross-section view of an integrated circuit die 810 implementing three isolated vertical double-diffused metal-oxide-semiconductor (VDMOS) field effect transistor devices shown in FIG. 15, and FIG. 8B, which shows a schematic illustration of a plan view of an integrated circuit die 810 implementing three isolated vertical double-diffused metal-oxide-semiconductor (VDMOS) field effect transistor devices shown in FIG. 15, in accordance with embodiments of the present disclosure. FIG. 8A shows a cross-section view of three isolated field effect transistors M1, M2, and M3 on a single field effect transistor (FET) die. In the cross-section view, the arrows on top of isolated field effect transistors M1, M2, and M3 are meant to show the direction of the clips 821, 822, and 823, respectively, that connect the respective source and drain of the isolated field effect transistors M1, M2, and M3.

FIG. 8B shows the plan view of an integrated circuit die implementing three isolated field effect transistors M1, M2, and M3. Metal clips 821, 822, and 823 are used to couple the source and drain of the isolated field effect transistors M1, M2, and M3. The metal clips 821, 822, and 823 may be copper clips. Furthermore, FIG. 8B shows the controller die 14 connected to the output of isolated field effect transistors M1, M2, and M3 via a wire-bond. Controller die 14 is also coupled to I/O1, I/O2, and C1K, which are inputs and/or outputs of the IC device, via wire-bond. Although shown one way in FIG. 8A and FIG. 8B, the position of the source and drain of the field effect transistors depends on the structure of the device. Therefore, other embodiments are appreciated. Furthermore, in some embodiments, the integrated circuit die can be flipped over and the gate can contact the quad flat no-lead package.

Power converter applications are typically high voltage and high current applications and are typically implemented on IC packages, such as surface mounted packages, flat no-lead packages, and quad flat no-lead packages.

In typical systems, power converter components implemented on a single die may be connected using wire-bonding or connected via the flip-chip method. Wire-bonding is advantageous for some applications because it allows for a higher number of pins per area because wire-bond connections are typically 10 to 20 microns apart whereas leadframe/flip chip connections are typically 400 microns apart.

However, these connection types have some disadvantages. For example, as the number of wire-bond connections increases, the overall package resistance increases significantly. Metal clips offer an alternative to wire-bonding and flip-chip connections.

Metal clips are advantageous because using metal clips reduces the overall package resistance as compared to wire-bonding implementations. Typically, a single metal clip may be utilized for connections on a single field effect transistor (FET) die.

However, when multiple isolated vertical devices are utilized on a single FET die, such as the vertical lateral double-diffused metal-oxide-semiconductor (LDMOS) and isolated vertical double-diffused metal-oxide-semiconductor (VDMOS) devices described in the present disclosure, multiple clips are needed to connect the drain and source of the field effect transistor devices.

In some embodiments, the metal clips are copper clips. As shown in FIGS. 8A and 8B, the copper clips 821, 822, and 823 can be soldered to the source and drain terminals of the isolated field effect transistor devices M1, M2, and M3. Power converters using the hybrid (co-packaged) approach described above can utilize copper clips to connect the source and drain terminals of the field effect transistor devices on the field effect transistor (FET) die.

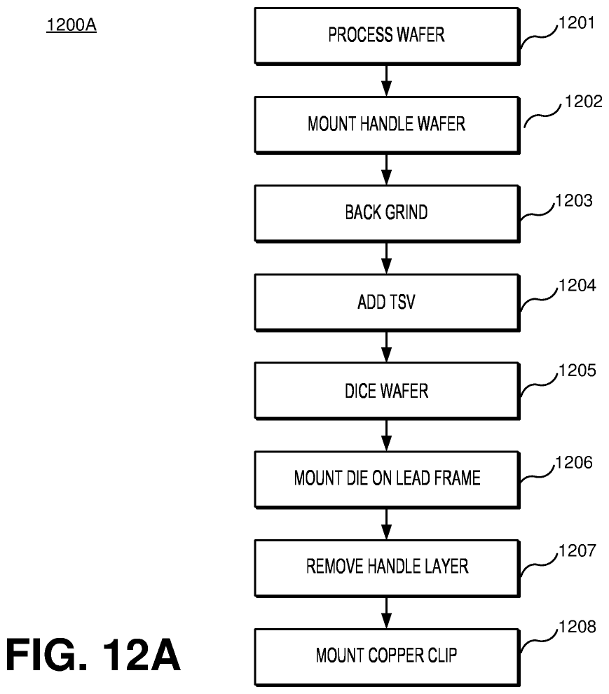

Reference is now made to FIG. 9, which is a plan view of an integrated circuit die 910 implementing replica field effect transistors 911, 914, 915, 917, in accordance with embodiments of the present disclosure. In certain power converter applications implemented on a field effect transistor (FET) die, it is beneficial to sense current through a field effect transistor (FET). This can be done by implementing replica field effect transistors (FETs). A replica field effect transistor (FET) is a replica of the type of field effect transistor (FET) that is implemented on the field effect transistor (FET) die. For example, if a field effect transistor (FET) die is implemented using the vertical LDMOS device described in the present disclosure, the replica field effect transistor (FET) would be a replica of the vertical LDMOS device that it is connected to.

Similarly, if a field effect transistor (FET) die is implemented using the isolated vertical double-diffused metal-oxide-semiconductor (VDMOS) device described in the present disclosure, the replica field effect transistor (FET) would be a replica of the isolated vertical double-diffused metal-oxide-semiconductor (VDMOS) device that it is connected to.

These replica field effect transistors (FETs) are added to the main field effect transistor (FET) device.

As shown in FIG. 9, the source and drain of the replica field effect transistor (FET) (e.g., replica FETs 911, 914, 915, 917) are electrically coupled to the source and drain of the main field effect transistor (FET) (e.g., main FETs associated with M1, M4, M5, M7), respectively. In some embodiments, replica field effect transistors (FETs) are smaller in size than the main field effect transistor (FET) device. In other embodiments, replica field effect transistors (FETs) are proportional in size to the main field effect transistor (FET) device. In some embodiments, main FET devices (e.g., first plurality of switches, second plurality of switches, etc.) may be different sizes.

In some embodiments, replica field effect transistors (FETs) may be used to measure the current through the main field effect transistor (FET) device. In other embodiments, replica field effect transistor (FETs) may be used to detect faults in the main field effect transistor (FET) device.

In still other embodiments, there can be multiple replica field effect transistors (FETs) on a single field effect transistor (FET) die. Similarly, in some embodiments, there can be multiple replica field effect transistor (FETs) on different field effect transistor (FET) dies.

As shown in FIG. 9, each of the field effect transistor (FET) switches M1, M4, M5, and M7 have replica field effect transistors (FET). As shown, the replica field effect transistors (FETs) couple to the source and drain of the main field effect transistor (FET) device.

In some embodiments, power converters implementing the hybrid (co-packaged) approach can utilize a single replica field effect transistor (FET) on a single field effect transistor (FET) dies and can utilize multiple replica field effect transistors (FETs) on a single field effect transistor (FET) die. In other embodiments, power converters implementing the hybrid (co-packaged) approach can utilize multiple replica devices on multiple field effect transistor (FET) dies.

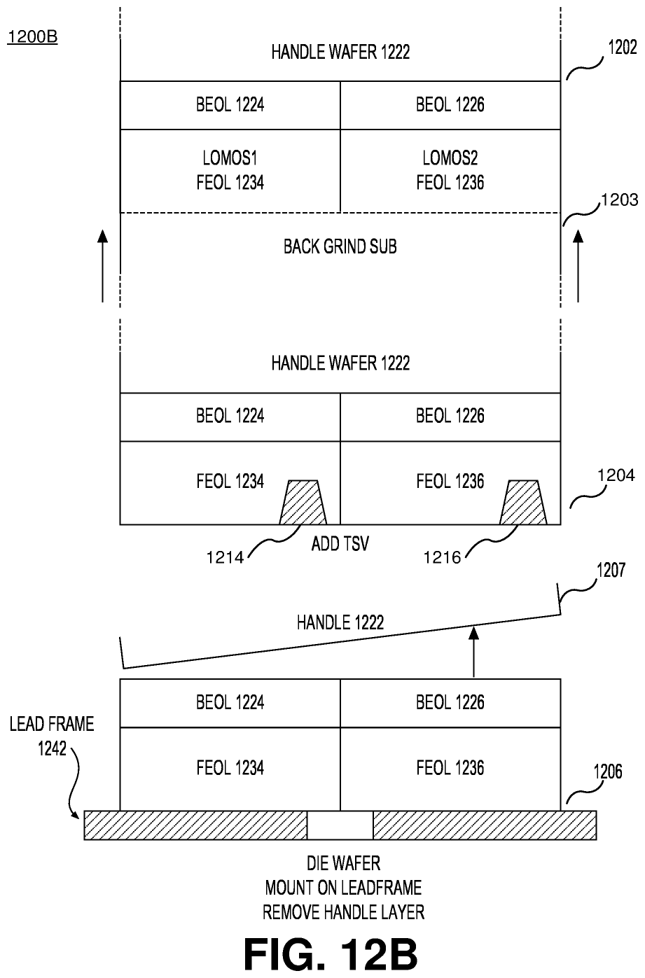

Power converters implementing the hybrid (co-packaged) approach described above can be implemented using a number of different field effect transistor (FET) devices with different structures. Examples of the types of field effect transistor structures that can be used are described in detail in the present disclosure, for example in FIGS. 10-17.

For example, power converters implementing the hybrid (co-packaged) approach can be implemented using vertical field effect transistor (FET) devices. In some embodiments, hybrid power converters can be implemented using the isolated vertical double-diffused metal-oxide-semiconductor (VDMOS) devices described in and the present disclosure, for example in FIGS. 15-17. In other embodiments, hybrid power converters can be implemented utilizing the vertical lateral double-diffused metal-oxide-semiconductor (LDMOS) devices described in the present disclosure, for example in FIGS. 10-14.

FIG. 10 is a schematic illustration of a cross-section view 1001 of an exemplary lateral double-diffused metal-oxide-semiconductor (LDMOS) field effect transistor device, in accordance with embodiments of the present disclosure. The lateral double-diffused metal-oxide-semiconductors (LDMOS) has a source S, drain D, gate G, and drift region N-DRIFT, where the source S, gate G, and drain D are all on the top surface of the device. As shown in the exemplary LDMOS field effect transistor device of FIG. 10, the source region may be p+ type, the drain region may be n+ type, and the drift region may be n-type (PMOS device). In other embodiments the source region may be n+ type, the drain region may be p+ type, and the drift region may be p-type (NMOS device). Lateral double-diffused metal-oxide-semiconductor (LDMOS) devices typically have lower routing loss than vertical double-diffused metal-oxide-semiconductor (VDMOS) devices. Therefore, it would be beneficial to create a device with the benefits of a lateral double-diffused metal-oxide-semiconductor (LDMOS) device, namely lower routing loss, and the structure of a vertical device to allow for vertical stacking. Lateral double-diffused metal-oxide-semiconductor (LDMOS) can be made vertical by applying single-layer transfer (SLT) to the lateral double-diffused metal-oxide-semiconductor (LDMOS) device.

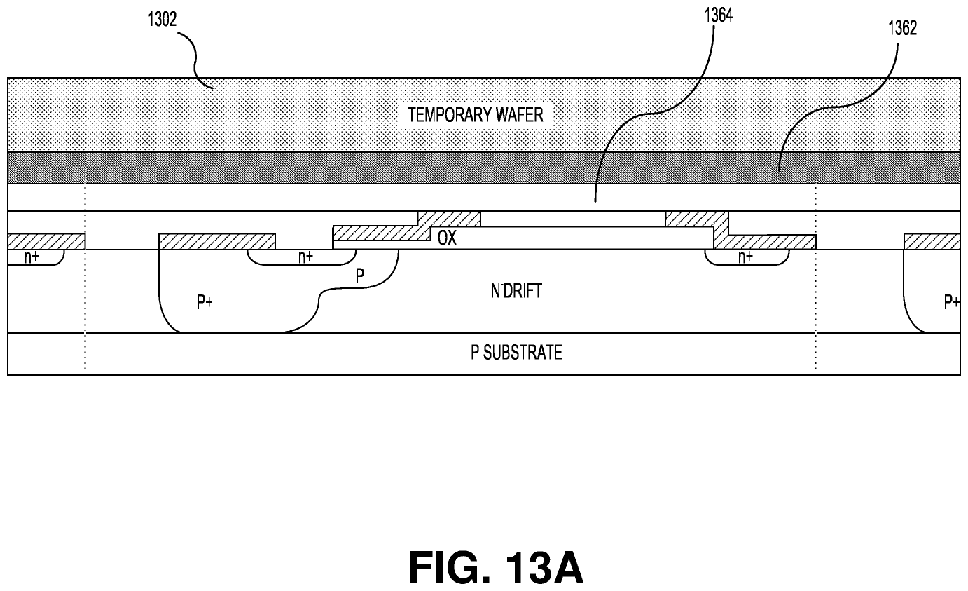

FIG. 11 is a schematic illustration of a cross-section view 1101 of an exemplary lateral double-diffused metal-oxide-semiconductor (LDMOS) field effect transistor device that is converted into a vertical device by etching a through-silicon via via1 from the bottom surface of the device to the drain D using single layer transfer (SLT), in accordance with embodiments of the present disclosure. As shown in FIG. 11, the source region may be p+ type, the drain region may be n+ type, and the drift region may be n-type (PMOS device). In some embodiments, the source region may be n+ type, the drain region may be p+ type, and the drift region may be p-type (NMOS device). Etching the through-silicon via via1 allows for connection to the drain D of the lateral double-diffused metal-oxide-semiconductor (LDMOS) through the bottom surface of the device.

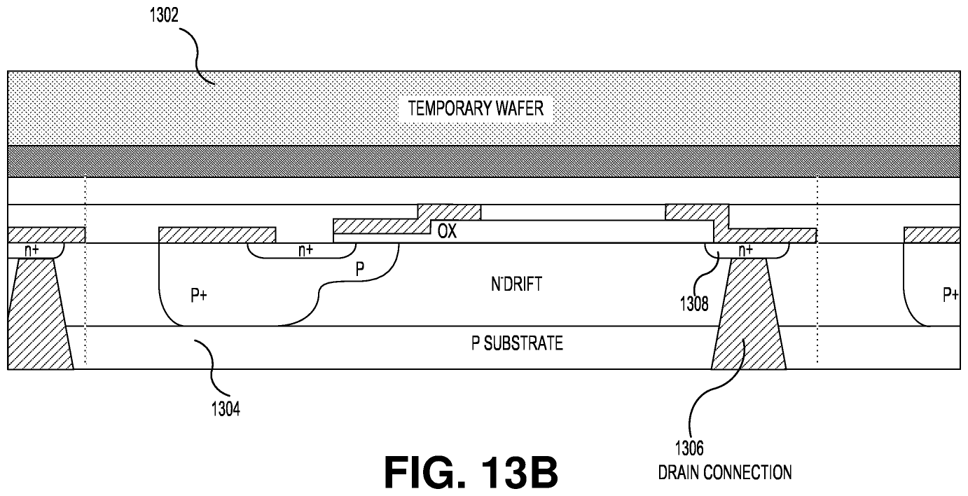

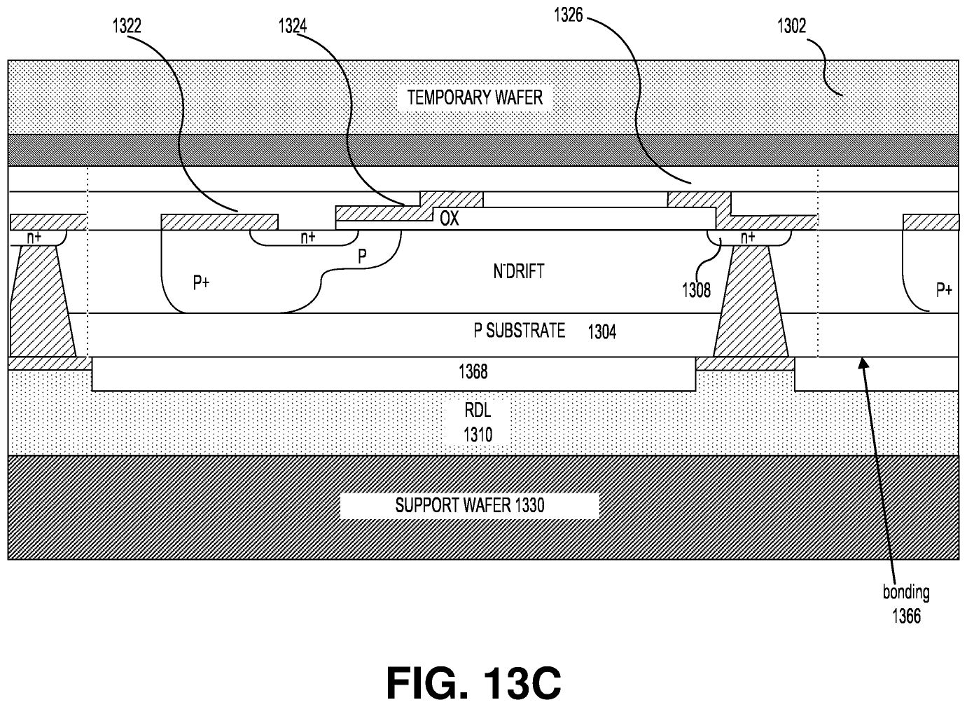

FIG. 12A shows a flow chart diagram 1200A of the process for manufacturing the lateral double-diffused metal-oxide-semiconductor (LDMOS) described in FIG. 11, in accordance with embodiments of the present disclosure. FIG. 12B shows a cross-sectional schematic diagram of the lateral double-diffused metal-oxide semiconductor (LDMOS) described in FIG. 11 during various steps in the STL manufacturing process outlined in FIG. 12A, in accordance with embodiments of the present disclosure. One of several ways to realize the structure of the lateral double-diffused metal-oxide-semiconductor (LDMOS) device shown in FIG. 11 may include a single layer transfer (SLT) fabrication technique illustrating only the active region for simplicity. A SLT fabrication technique may include one bonding process to form a device or a structure, such as a device used in a switched capacitor power converter. It is to be appreciated that steps may be added, removed, reordered, replaced, or modified, as appropriate to form structures having desirable physical and electrical characteristics based on the application and desired product characteristics. The disclosed embodiments show that SLT techniques can be used for fabricating power converters. SLT techniques may be understood to be limited to bonding layers using “sacrificial” or “dumb” substrates. The disclosed embodiments, however, recognize, for example, that SLT techniques can be used to bond substrates that include one or more passive devices such as capacitors and inductors, in addition to providing overall structural support, as opposed to only sacrificial or dumb substrates.

With reference to FIGS. 12A and 12B, the SLT process consists mainly of eight steps and allows for access to either the source terminal or the drain terminal of the lateral double-diffused metal-oxide-semiconductor (LDMOS) on either the top surface or bottom surface of the device. Step 1201 is to process the wafer. At step 1202, a handle wafer (also known and referred to as a temporary wafer) may be attached to the top surface of the device and the device is flipped over so the substrate is on top. At step 1203, the substrate may be back-grinded down sufficiently close to the drift region. In some embodiments, the substrate is back-grinded to a minimum depth of 50 microns. In some embodiments, the substrate may be back-grinded to a depth greater than 50 microns. At step 1204, a through-silicon via (TSV) may be etched through the device to the drain or source region (e.g., an integrated circuit die may include a TSV configured to form an electrical connection to either drain terminals or source terminals of the plurality of first switches, the plurality of second switches, etc.).

The TSV may be formed using, for example, deep reactive ion etching, isotropic radial etching, reactive ion beam etching, ion milling, ion beam assisted etching, or sputter etching. The resulting device has the benefits of a lateral device (e.g., lower routing loss), but allows for the advantages associated with a vertical device structure (e.g., vertical stacking of multiple devices, vertical stacking of integrated circuit dies, etc.). The resulting device may be implemented on an integrated circuit die as, for example, a switch in a switched capacitor circuit.

At step 1205, after the through-silicon via is formed, the wafer may be diced and at step 1206, the diced wafer may be mounted onto the lead frame. At step 1207, the handle wafer can be removed and at step 1208, a copper clip can be mounted to connect the source and drain.

With reference to FIG. 12B, as described above with respect to FIG. 12A, the SLT process may include the following steps. Step 1201 of the SLT process is to process the wafer. At step 1202, a handle wafer 1222 (also known and referred to as a temporary wafer) may be attached to the top surface of the devices and the devices may be flipped over so the substrate is at the top. The devices may include back-end-of-line (BEOL) 1224, BEOL 1226, LDMOS1 front-end-of-line (FEOL) 1234, and LDMOS2 FEOL 1236.

At step 1203, the substrate may be back-grinded down sufficiently close to the drift region. In some embodiments, the substrate is back-grinded to a minimum depth of 50 microns. In some embodiments, the substrate may be back-grinded to a depth greater than 50 microns. At step 1204, through-silicon vias (TSVs) 1214 and 1216 may be etched through the devices to the drain or source. At step 1205, after the TSVs are formed, the wafer may be diced. At step 1206, the diced wafer may be mounted onto a lead frame 1242. At step 1207, the handle wafer 1222 can be removed. At step 1208, a copper clip can be mounted to connect the source and drain.

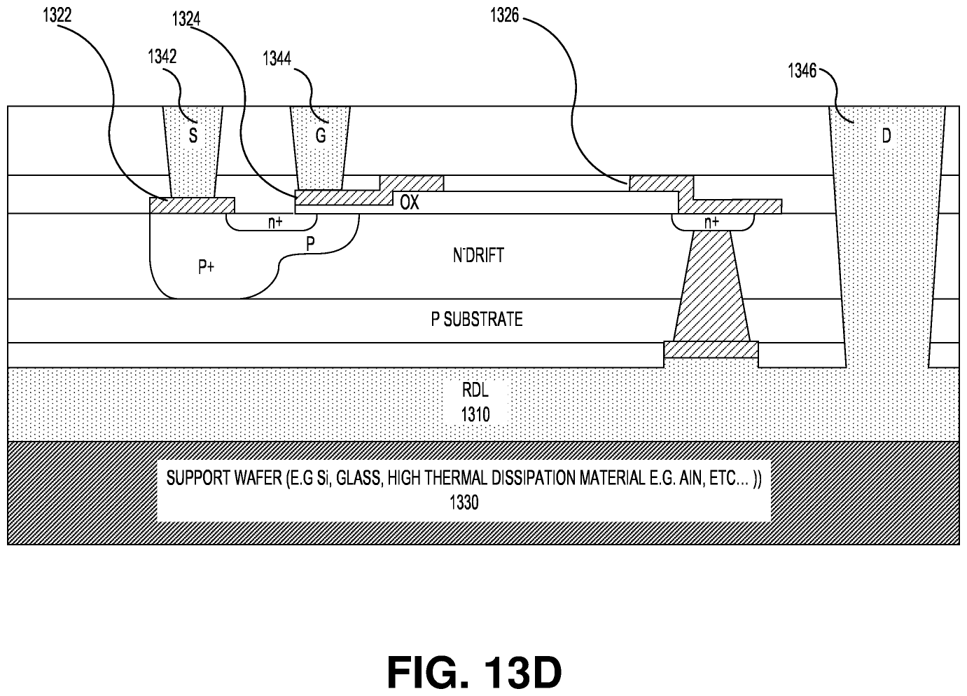

FIGS. 13A-13D show a process for manufacturing the lateral double-diffused metal-oxide-semiconductor (LDMOS) described in FIG. 11, in accordance with embodiments of the present disclosure.

As shown in FIG. 13A, a temporary wafer 1302 can be added to an extended drain metal-oxide-semiconductor device (EDMOS). The temporary wafer 1302 may be bonded to an insulating layer 1364 (e.g., an oxide) on the surface of the device by an adhesion layer 1362 (e.g., a bonding oxide). In another embodiment, a polymer bonding (e.g., benzocyclobutene (BCB)) can be used to bond the temporary wafer 1302 to the surface of the device. In some embodiments, insulating layer 1364 may be planarized to enable bonding.

As shown in FIG. 13B, the EDMOS device is then flipped over. After flipping the EDMOS device over, the substrate 1304 may be back-grinded down sufficiently close to the drift region. In some embodiments, the substrate 1304 is back-grinded to a minimum depth of 50 microns. In some embodiments, the substrate 1304 may be back-grinded to a depth greater than 50 microns. A trench, or end connection, 1306 may then be etched through the device to the drain or source region 1308 to create a drain connection or source connection. The trench, or end connection, may be etched by, for example, deep reactive ion etching, isotropic radial etching, reactive ion beam etching, ion milling, ion beam assisted etching, or sputter etching. The connection to the source or drain region may then be completed using conductive materials, such as tungsten or copper, and routed throughout the device.

As shown in FIG. 13C, the EDMOS device is flipped back over so that the source 1322, gate 1324, and drain 1326 are on the top surface of the device. The redistributing layer (RDL) 1310 is then bonded to the top layer. The RDL 1310 may be bonded to the top surface of the EDMOS device using a hybrid bonding process. The RDL 1310 includes metal layers that are built in to allow connection to the drain region 1308. The RDL 1310 may be made out of highly conductive material, such as, for example, copper or aluminum.

In some embodiments, a layer 1368 may be above RDL 1310 and bonded to substrate 1304 by bonding 1366. In some embodiments, layer 1368 may be a polymide layer. In some embodiments, the polyimide layer 1368 may help isolate the RDL 1310 and substrate 1304 and may allow or facilitate bonding. Without the polyimide layer 1368, conduction may occur between RDL 1310 and substrate 1304 at unwanted locations. In some embodiments, layer 1368 may be an oxide layer.

As shown in FIG. 13C, a support wafer 1330 is also added to the EDMOS device. The support wafer 1330 can be fabricated out of, for example, silicon or glass, high thermal dissipation material, or some other highly insulating material.

As shown in FIG. 13D, the temporary wafer 1302 is removed. The temporary wafer 1302 may be removed by using a blade or by debonding the temporary wafer 1302. Once the temporary wafer 1302 is removed, the source, gate, and drain connections 1342, 1344, 1346, respectively, are created on the top surface of the wafer. As shown in FIG. 13D, the drain connection 1346 is through the RDL 1310.

In yet another embodiment, the support wafer 1330 shown in FIGS. 13C and 13D may be excluded and the RDL 1310 may be made thicker. In this embodiment, the RDL 1310 may be, for example, greater than 100 microns thick. Doing so enables connection to the drain 1326 through the bottom of the EDMOS device.

In this embodiment, the device can be coupled to other EDMOS devices by a single metal layer on the top surface of the device and a think single metal layer on the bottom surface of the device. This is advantageous, particularly in low voltage devices, because it reduces the overall routing resistance in the device. In prior art low voltage devices, using interdigitated connections on only the top surface of the device creates performance issues because of the overall routing resistance of the device is high because of the interdigitated connections. Because using thick single metal layers on the top and bottom surfaces of the EDMOS device reduces the routing resistance, performance is improved at low voltages. This solution also enables smaller MOS devices to be used because the overall routing resistance is much lower.

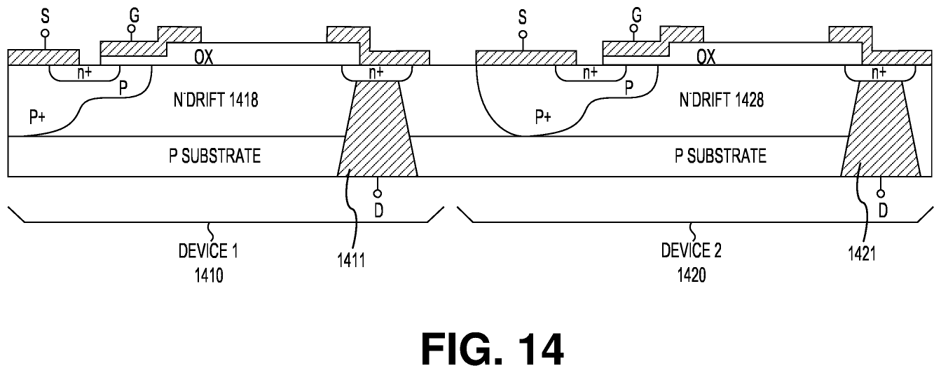

FIG. 14 is a schematic illustration of a cross-section view of two isolated lateral double-diffused metal-oxide-semiconductors (LDMOS) field effect transistor devices 1410 and 1420, in accordance with embodiment of the present disclosure. Both of the lateral double-diffused metal-oxide-semiconductors (LDMOS) field effect transistor devices 1410 and 1420 have had a TSV 1411 and 1421, respectively, etched into them. These devices are considered isolated due to the TSVs 1411 and 1421 separating device 1 1410 and device 2 1420. In some embodiments, these devices can be vertically stacked upon one another (e.g., vertical stacking of integrated circuit dies, etc.).

The voltage rating of lateral double-diffused metal-oxide-semiconductors (LDMOS) field effect transistor devices can be changed by adjusting the length of the drift region N-DRIFT 1418, 1428 and adjusting the amount of doping. Therefore, lateral double-diffused metal-oxide-semiconductors (LDMOS) field effect transistor devices can have multiple different voltage rated devices on the same die.

FIG. 15 is a schematic illustration of a cross-section view of two exemplary vertical double-diffused metal-oxide-semiconductor (VDMOS) field effect transistor device where the drain regions 1516 are connected to one another, in accordance with embodiments of the present disclosure. As shown in FIG. 15, the vertical double-diffused metal-oxide-semiconductor (VDMOS) field effect transistor devices may have a source 1512, drain 1516, gate 1514, and drift region 1518, where the source region 1512 and drain regions 1516 may be located on opposite sides of the device. The source region may be p+ type, the drain region may be n+ type, and the drift region may be n-type. In some embodiments, the source region may be n+ type, the drain region may be p+ type, and the drift region is p-type.

The source region may be on the top surface of the device and the drain region on the bottom surface, as shown in FIG. 15. In some embodiments, the drain region may be on the top surface of the device and the source region may be on the bottom surface.

When multiple vertical double-diffused metal-oxide-semiconductor (VDMOS) field effect transistor devices are implemented on a single die, the drain regions are connected to one another as shown in FIG. 15. Therefore, when multiple vertical double-diffused metal-oxide-semiconductor (VDMOS) field effect transistor devices are implemented on a single die, isolation is needed to prevent the drain regions from being connected to one another and to allow for devices with different voltage ratings.

In order to isolate multiple vertical double-diffused metal-oxide-semiconductor (VDMOS) field effect transistor devices on a single die, deep trenches need to be formed all the way around the vertical double-diffused metal-oxide-semiconductor (VDMOS) field effect transistor devices device and filled with isolating material.

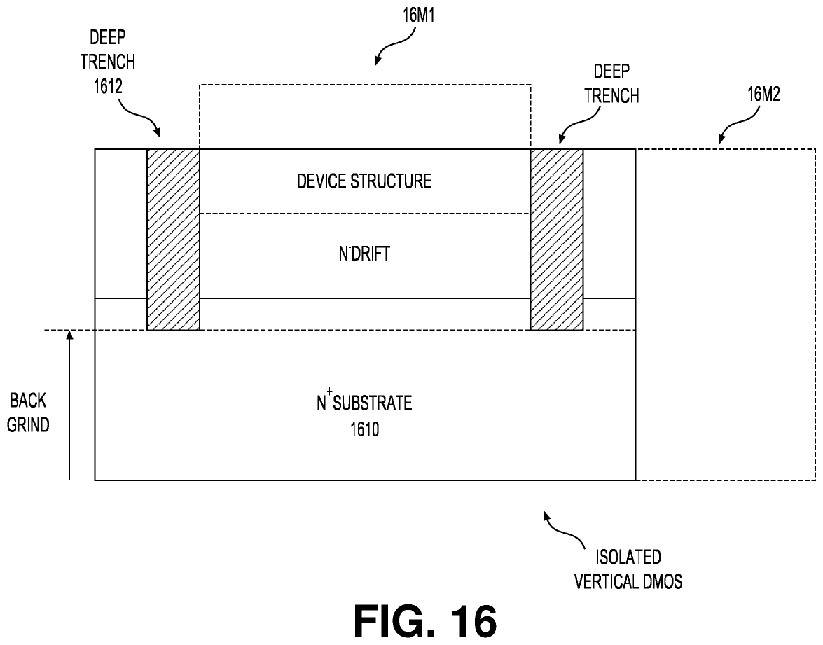

FIG. 16 is a schematic illustration of a cross-section view of an exemplary isolated vertical double-diffused metal-oxide-semiconductor (VDMOS) field effect transistor device, in accordance with embodiments of the present disclosure.

FIG. 16 shows two vertical double-diffused metal-oxide-semiconductor (VDMOS) field effect transistor (FET) devices, 16M1 and 16M2. As shown, VDMOS FET devices 16M1 and 16M2 are isolated from one another by a deep trench 1612 filled with insulating material. The isolating trenches 1612 may be formed by dry etching the wafer. The isolation trenches may be formed using, for example, deep reactive ion etching, isotropic radial etching, reactive ion beam etching, ion milling, ion beam assisted etching, or sputter etching. In some embodiments, the isolation trench 1612 may be formed by doping the region between VDMOS FET devices 16M1 and 16M2 (e.g., an integrated circuit die may include isolation trenches configured to electrically isolate a plurality of first switches and a plurality of second switches from each other, etc.).

The N+ (PMOS) or P+ (NMOS) substrate 1610 (e.g., of an integrated circuit die) may be back-grinded until the isolating trench 1612 is through the bottom of the drain. After the substrate 1610 is back ground, the isolating trench 1612 may be filled with an electrically isolating material. The electrically isolating material may be, for example, silicon or silicon dioxide.

The resulting device allows multiple vertical double-diffused metal-oxide-semiconductor (VDMOS) field effect transistor devices to be implemented on a single die. The resulting device may also be vertically stacked due to the vertical structure.

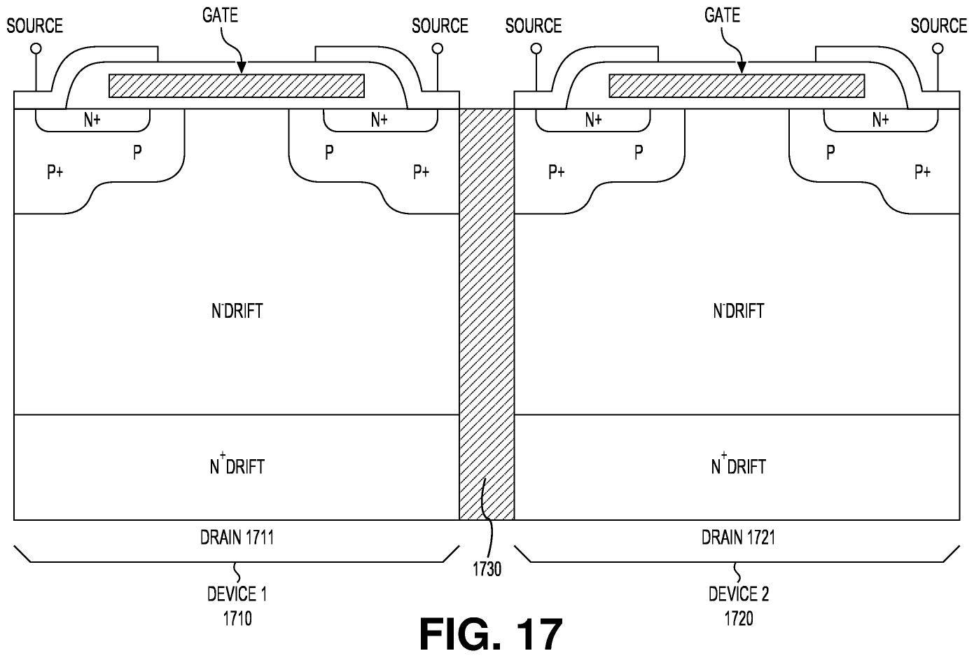

FIG. 17 is a schematic illustration of a cross-section view of isolated vertical double-diffused metal-oxide-semiconductor (VDMOS) field effect transistor devices 1710 and 1720, in accordance with embodiments of the present disclosure. As shown in FIG. 17, the drain regions 1711 and 1721 of the two devices 1710 and 1720 are isolated (e.g., by isolating material 1730) from one another. In some embodiments, the two isolated devices 1710 and 1720 may have the same voltage rating. In some embodiments, the two isolated devices 1710 and 1720 may have a different voltage rating.

In some embodiments, hybrid power converters utilizing isolated vertical double-diffused metal-oxide-semiconductor (VDMOS) and vertical lateral double-diffused metal-oxide-semiconductor (LDMOS) devices can have the sources and drains of said devices coupled using metal clips. In some embodiments, the metal clips may be copper clips.

In some embodiments, hybrid power converters utilizing isolated vertical double-diffused metal-oxide-semiconductor (VDMOS) and vertical lateral double-diffused metal-oxide-semiconductor (LDMOS) devices can have corresponding replica devices, as described above.

In some embodiments, hybrid power converters can utilize replica devices to sense current. In some embodiments, hybrid power converters can utilize replica devices to detect faults.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiment of the specification. Certain features described in the context of various embodiments are not to be considered essential features of those embodiments unless the embodiment is inoperative without those elements.

The embodiments may further be described using the following clauses:

1. An apparatus comprising:
an integrated circuit package including:
   a first integrated circuit die electrically coupled to a lead frame;
      wherein the first integrated circuit die includes a plurality of first switches and a plurality of second switches;
      wherein the plurality of first switches and the plurality of second switches are interconnected with a plurality of first capacitors to form a first switched capacitor circuit, wherein the first switched capacitor circuit is configured to transition between at least two states in response to switching of the plurality of first switches and the plurality of second switches; and
   a second integrated circuit die;
      wherein the second integrated circuit die includes a controller circuit that is electrically coupled to control switching of the plurality of first switches and the plurality of second switches; and
   a third integrated circuit die electrically coupled to the lead frame;
      wherein the third integrated circuit die includes a plurality of third switches and a plurality of fourth switches;
      wherein the plurality of third switches and the plurality of fourth switches are interconnected with a plurality of second capacitors to form a second switched capacitor circuit, wherein the second switched capacitor circuit is configured to transition between at least two states in response to switching of the plurality of third switches and the plurality of fourth switches; and
      wherein the controller circuit is electrically coupled to control switching of the plurality of third switches and the plurality of fourth switches;
wherein the first integrated circuit die, the second integrated circuit die, and the third integrated circuit die are co-packaged; and
wherein at least one of the plurality of first switches and the plurality of second switches has a different current rating than at least one of the plurality of third switches and the plurality of fourth switches.
   2. The apparatus of clause 1, wherein the first switched capacitor circuit has a power rating of about 100 Watts to about 1,000 Watts.
   3. The apparatus of clause 1, wherein the integrated circuit package is a surface-mounted package.
   4. The apparatus of clause 3, wherein the integrated circuit package is a flat no-lead package.
   5. The apparatus of clause 4, wherein the integrated circuit package is a quad flat no-lead package.
   6. The apparatus of clause 1, wherein the controller circuit includes one or more complementary metal-oxide-semiconductor field effect transistors.
   7. The apparatus of clause 1, wherein the plurality of first switches and the plurality of second switches each include one or more double-diffused metal-oxide-semiconductor field effect transistors.
   8. The apparatus of clause 1, wherein the controller circuit is configured to control switching of switches having a current rating of between about 10 amps and about 40 amps.
   9. The apparatus of clause 1, wherein the first integrated circuit die includes a first replica switch, wherein at least two terminals of the first replica switch are electrically connected to at least two corresponding terminals of one switch of the plurality of first switches or the plurality of second switches.
   10. The apparatus of clause 9, wherein the first replica switch is smaller in size than the one switch to which its terminals are electrically connected.
   11. The apparatus of clause 9, wherein the first replica switch is configured to sense a current flowing through the one switch to which its terminals are electrically connected.
   12. The apparatus of clause 9, wherein the first replica switch is configured to detect a fault associated with the one switch to which its terminals are electrically connected.
   13. The apparatus of clause 9, wherein the first integrated circuit die includes a second replica switch, wherein at least two terminals of the second replica switch are electrically connected to at least two corresponding terminals of another switch of the plurality of first switches or the plurality of second switches;
wherein the one switch and the another switch are of different sizes; and
wherein the first replica switch and the second replica switch are sized in proportion to the one switch and the another switch respectively.
   14. The apparatus of clause 13, wherein the second replica switch is smaller than the another switch to which its terminals are electrically connected.
   15. The apparatus of clause 13, wherein the second replica switch is configured to sense a current flowing through the another switch to which its terminals are electrically connected.
   16. The apparatus of clause 13, wherein the second replica switch is configured to detect a fault associated with the another switch to which its terminals are electrically connected.
   17. The apparatus of clause 1, wherein the first integrated circuit die electrically coupled to the lead frame using wire-bonding.
   18. The apparatus of clause 1, wherein the second integrated circuit die electrically coupled to the lead frame using flip-chip bonding.
   19. The apparatus of clause 1, wherein the plurality of first switches and the plurality of second switches each include one or more lateral double-diffused metal-oxide semiconductor field effect transistors.
   20. The apparatus of clause 19, wherein the first integrated circuit die includes a through-silicon via configured to form an electrical connection to either drain terminals or source terminals of either the plurality of first switches or the plurality of second switches.
   21. The apparatus of clause 20, wherein the through-silicon via is made using a single transfer layer process.
   22. The apparatus of clause 19, the apparatus further comprising:
a fourth integrated circuit die electrically coupled to the lead frame;
   wherein the fourth integrated circuit die includes a plurality of fifth switches and a plurality of sixth switches;
   wherein the plurality of fifth switches and the plurality of sixth switches are interconnected with a plurality of third capacitors to form a third switched capacitor circuit, wherein the third switched capacitor circuit is configured to transition between at least two states in response to switching of the plurality of fifth switches and the plurality of sixth switches; and
wherein the controller circuit is electrically coupled to control switching of the plurality of fifth switches and the plurality of sixth switches; and
wherein the first integrated circuit die and the fourth integrated circuit die are vertically stacked.
   23. The apparatus of clause 19, wherein the first integrated circuit die includes a plurality of metal clips coupled between at least two pairs of source and drain terminals of the plurality of first switches or the plurality of second switches.
   24. The apparatus of clause 23, wherein the metal clips are copper clips that are soldered to the source and drain terminals.
   25. The apparatus of clause 1, wherein the plurality of first switches and the plurality of second switches each include one or more vertical double-diffused metal-oxide semiconductor field effect transistors.
   26. The apparatus of clause 25, wherein the first integrated circuit die includes a plurality of isolation trenches configured to electrically isolate the plurality of first switches and the plurality of second switches from each other.
   27. The apparatus of clause 26, wherein the plurality of isolation trenches are formed using deep reactive ion etching.
   28. The apparatus of clause 26, wherein an insulating layer is deposited in the plurality of isolation trenches.
   29. The apparatus of clause 26, wherein a substrate of the first integrated circuit die is ground to reduce its thickness compared to a wafer from which the first integrated circuit die was made.
   30. The apparatus of clause 25, wherein the first integrated circuit die includes a plurality of metal clips coupled between at least two pairs of source and drain terminals of the plurality of first switches or the plurality of second switches.
   31. The apparatus of clause 30, wherein the metal clips are copper clips that are soldered to the source and drain terminals.
   32. The apparatus of clause 1, wherein the plurality of first switches and the plurality of second switches are lateral double-diffused metal oxide semiconductor devices.
   33. An apparatus comprising:
a vertical double-diffused metal-oxide-semiconductor field effect transistor comprising a drift region, a source region, a drain region, and a gate;
   wherein the vertical double-diffused metal-oxide-semiconductor field effect transistor is isolated by an isolation trench formed around the vertical double-diffused metal-oxide-semiconductor field effect transistor;
   wherein the isolation trench is filled with an electrically isolating material; and
   wherein the isolation trench goes through the bottom of the drain.
      34. The apparatus of clause 33, wherein the drift region is n-type, the source region is p type, the drain is n+ type.
      35. The apparatus of clause 33, wherein the electrically isolating material that fills the isolation trench is silicon.
      36. The apparatus of clause 33, wherein the electrically isolating material that fills the isolation trench is silicon dioxide.
      37. The apparatus of clause 33, wherein the isolation trench is formed using deep reactive ion etching.
      38. The apparatus of clause 33, wherein the isolation trench is formed using isotropic radial etching.
      39. The apparatus of clause 33, wherein the isolation trench is formed using reactive ion beam etching.
      40. The apparatus of clause 33, wherein the isolation trench is formed using ion milling.
      41. The apparatus of clause 33, wherein the isolation trench is formed using ion beam assisted etching.
      42. The apparatus of clause 33, wherein the isolation trench is formed using sputter etching.
      43. The apparatus of clause 33, wherein the drain is on the top surface of the vertical double-diffused metal-oxide-semiconductor field effect transistor and the source is on the bottom surface of the vertical double-diffused metal-oxide-semiconductor field effect transistor.
      44. The apparatus of clause 33, further comprising:
an integrated circuit package including:
   a first integrated circuit die electrically coupled to a lead frame;
      wherein the first integrated circuit die includes a plurality of first switches and a plurality of second switches;
      wherein the plurality of first switches and the plurality of second switches are interconnected with a plurality of first capacitors to form a first switched capacitor circuit, wherein the first switched capacitor circuit transitions between at least two states in response to switching of the plurality of first switches and the plurality of second switches; and
      wherein the plurality of first switches and the plurality of second switches each include one or more of the vertical double-diffused metal-oxide semiconductor field effect transistors wherein the vertical double-diffused metal-oxide semiconductor field effect transistors are electrically isolated from each other by the isolation trenches.
         45. The apparatus of clause 44, wherein the first switched capacitor circuit has a power rating of about 100 Watts to about 1,000 Watts.
         46. The apparatus of clause 44, wherein the integrated circuit package is a surface-mounted package.
         47. The apparatus of clause 46, wherein the integrated circuit package is a flat no-lead package.
         48. The apparatus of clause 47, wherein the integrated circuit package is a quad flat no-lead package.
         49. The apparatus of clause 44, wherein the first integrated circuit die includes a first replica switch, wherein at least two terminals of the first replica switch are electrically connected to at least two corresponding terminals of one switch of the plurality of first switches or the plurality of second switches.
         50. The apparatus of clause 49, wherein the first replica switch is smaller in size than the one switch to which its terminals are electrically connected.
         51. The apparatus of clause 49, wherein the first replica switch senses a current flowing through the one switch to which its terminals are electrically connected.
         52. The apparatus of clause 49, wherein the first replica switch detects a fault associated with the one switch to which its terminals are electrically connected.
         53. The apparatus of clause 49, wherein the first integrated circuit die includes a second replica switch, wherein at least two terminals of the second replica switch are electrically connected to at least two corresponding terminals of another switch of the plurality of first switches or the plurality of second switches;
wherein the one switch and the another switch are of different sizes; and
wherein the first replica switch and the second replica switch are sized in proportion to the one switch and the another switch respectively.
   54. The apparatus of clause 53, wherein the second replica switch is smaller than the another switch to which its terminals are electrically connected.
   55. The apparatus of clause 53, wherein the second replica switch senses a current flowing through the another switch to which its terminals are electrically connected.
   56. The apparatus of clause 53, wherein the second replica switch detects a fault associated with the another switch to which its terminals are electrically connected.
   57. The apparatus of clause 44, wherein the first integrated circuit die is electrically coupled to the lead frame using flip-chip bonding.
   58. The apparatus of clause 33, further comprising:
a second integrated circuit die electrically coupled to the lead frame;
   wherein the second integrated circuit die includes a plurality of third switches and a plurality of fourth switches;
   wherein the plurality of third switches and the plurality of fourth switches are interconnected with a plurality of second capacitors to form a second switched capacitor circuit, wherein the second switched capacitor circuit transitions between at least two states in response to switching of the plurality of third switches and the plurality of fourth switches; and
   wherein the plurality of third switches and the plurality of fourth switches each include one or more of the vertical double-diffused metal-oxide semiconductor field effect transistors wherein the vertical double-diffused metal-oxide semiconductor field effect transistors are electrically isolated from each other by the isolation trenches.
      59. The apparatus of clause 58, wherein at least one of the plurality of first switches and the plurality of second switches has a different current rating than at least one of the plurality of third switches and the plurality of fourth switches.
      60. The apparatus of clause 44, wherein the first integrated circuit die includes a plurality of metal clips coupled between at least two pairs of source and drain terminals of the plurality of first switches or the plurality of second switches.
      61. The apparatus of clause 60, wherein the metal clips are copper clips that are soldered to the source and drain terminals.
      62. An apparatus comprising:
a lateral double-diffused metal-oxide-semiconductor field effect transistor comprising a drift region, a source region, a drain region, a gate, and a substrate;
   wherein the lateral double-diffused metal-oxide-semiconductor field effect transistor has a through-silicon via for formation of an electrical connection to the drain from the bottom surface of the lateral double-diffused metal-oxide-semiconductor field effect transistor.
      63. The apparatus of clause 62, wherein the through-silicon via is formed using a single layer transfer process.
      64 The apparatus of clause 63, wherein the single layer transfer process includes back-grinding and etching the substrate and etching the through-silicon via.
      65. The apparatus of clause 64, wherein the through-silicon via is formed using deep reactive ion etching.
      66. The apparatus of clause 64, wherein the through-silicon via is formed using isotropic radial etching.
      67. The apparatus of clause 64, wherein the through-silicon via is formed using reactive ion beam etching.
      68. The apparatus of clause 64, wherein the through-silicon via is formed using ion milling.
      69. The apparatus of clause 64, wherein the through-silicon via is formed using ion beam assisted etching.
      70. The apparatus of clause 64, wherein the through-silicon via is formed using sputter etching.
      71. The apparatus of clause 64, wherein the substrate is back-ground and etched down to a thickness of 50 microns or more.
      72. The apparatus of clause 62, wherein the lateral double-diffused metal-oxide-semiconductor field effect transistor has a through-silicon via for formation of an electrical connection to the source from the bottom surface of the lateral double-diffused metal-oxide-semiconductor field effect transistor.
      73. The apparatus of clause 62, further comprising:
an integrated circuit package:
   a first integrated circuit die electrically coupled to a lead frame;
      wherein the first integrated circuit die includes a plurality of first switches and a plurality of second switches;
      wherein the plurality of first switches and the plurality of second switches are interconnected with a plurality of first capacitors to form a first switched capacitor circuit, wherein the first switched capacitor circuit transitions between at least two states in response to switching of the plurality of first switches and the plurality of second switches; and
      wherein the plurality of first switches and the plurality of second switches each include one or more of the lateral double-diffused metal-oxide semiconductor field effect transistors.
         74. The apparatus of clause 73, wherein the first switched capacitor circuit has a power rating of about 100 Watts to about 1,000 Watts.
         75. The apparatus of clause 73, wherein the integrated circuit package is a surface-mounted package.
         76. The apparatus of clause 75, wherein the integrated circuit package is a flat no-lead package.
         77. The apparatus of clause 76, wherein the integrated circuit package is a quad flat no-lead package.
         78. The apparatus of clause 73, wherein the first integrated circuit die includes a first replica switch, wherein at least two terminals of the first replica switch are electrically connected to at least two corresponding terminals of one switch of the plurality of first switches or the plurality of second switches.
         79. The apparatus of clause 78, wherein the first replica switch is smaller than the one switch to which its terminals are electrically connected.
         80. The apparatus of clause 78, wherein the first replica switch senses a current flowing through the one switch to which its terminals are electrically connected.
         81. The apparatus of clause 78, wherein the first replica switch detects a fault associated with the one switch to which its terminals are electrically connected.
         82. The apparatus of clause 78, wherein the first integrated circuit die includes a second replica switch, wherein at least two terminals of the second replica switch are electrically connected to at least two corresponding terminals of another switch of the plurality of first switches or the plurality of second switches;
wherein the one switch and the another switch are of different sizes; and
wherein the first replica switch and the second replica switch are sized in proportion to the one switch and the another switch respectively.
   83. The apparatus of clause 82, wherein the second replica switch is smaller than the another switch to which its terminals are electrically connected.
   84. The apparatus of clause 82, wherein the second replica switch senses a current flowing through the another switch to which its terminals are electrically connected.
   85. The apparatus of clause 82, wherein the second replica switch detects a fault associated with the another switch to which its terminals are electrically connected.
   86. The apparatus of clause 73, wherein the first integrated circuit die is electrically coupled to the lead frame using flip-chip bonding.
   87. The apparatus of clause 62, further comprising:
a second integrated circuit die electrically coupled to the lead frame;
   wherein the second integrated circuit die includes a plurality of third switches and a plurality of fourth switches;
   wherein the plurality of third switches and the plurality of fourth switches are interconnected with a plurality of second capacitors to form a second switched capacitor circuit, wherein the second switched capacitor circuit transitions between at least two states in response to switching of the plurality of third switches and the plurality of fourth switches; and
   wherein the plurality of third switches and the plurality of fourth switches each include one or more of the lateral double-diffused metal-oxide semiconductor field effect transistors.
      88. The apparatus of clause 87, wherein at least one of the plurality of first switches and the plurality of second switches has a different current rating than at least one of the plurality of third switches and the plurality of fourth switches.
      89. The apparatus of clause 87, wherein the first integrated circuit die and second integrated circuit die are vertically stacked on one another.
      90. The apparatus of clause 73, wherein the first integrated circuit die includes a plurality of metal clips coupled between at least two pairs of source and drain terminals of the plurality of first switches or the plurality of second switches.
      91. The apparatus of clause 90, wherein the metal clips are copper clips that are soldered to the source and drain terminals.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus comprising:
an integrated circuit package including:
a first integrated circuit die electrically coupled to a lead frame;
wherein the first integrated circuit die includes a plurality of first switches and a plurality of second switches;
wherein the plurality of first switches and the plurality of second switches are interconnected with a plurality of first capacitors to form a first switched capacitor circuit, wherein the first switched capacitor circuit is configured to transition between at least two states in response to switching of the plurality of first switches and the plurality of second switches; and
a second integrated circuit die;
wherein the second integrated circuit die includes a controller circuit that is electrically coupled to control switching of the plurality of first switches and the plurality of second switches; and
a third integrated circuit die electrically coupled to the lead frame;
wherein the third integrated circuit die includes a plurality of third switches and a plurality of fourth switches;
wherein the plurality of third switches and the plurality of fourth switches are interconnected with a plurality of second capacitors to form a second switched capacitor circuit, wherein the second switched capacitor circuit is configured to transition between at least two states in response to switching of the plurality of third switches and the plurality of fourth switches; and
wherein the controller circuit is electrically coupled to control switching of the plurality of third switches and the plurality of fourth switches;
wherein the first integrated circuit die, the second integrated circuit die, and the third integrated circuit die are co-packaged; and
wherein at least one of the plurality of first switches and the plurality of second switches has a different current rating than at least one of the plurality of third switches and the plurality of fourth switches.

2. The apparatus of claim 1, wherein the first switched capacitor circuit has a power rating of about 100 Watts to about 1,000 Watts.

3. The apparatus of claim 1, wherein the integrated circuit package is a surface-mounted package.

4. The apparatus of claim 3, wherein the integrated circuit package is a flat no-lead package.

5. The apparatus of claim 4, wherein the integrated circuit package is a quad flat no-lead package.

6. The apparatus of claim 1, wherein the controller circuit includes one or more complementary metal-oxide-semiconductor field effect transistors.

7. The apparatus of claim 1, wherein the plurality of first switches and the plurality of second switches each include one or more double-diffused metal-oxide-semiconductor field effect transistors.

8. The apparatus of claim 1, wherein the controller circuit is configured to control switching of switches having a current rating of between about 10 amps and about 40 amps.

9. The apparatus of claim 1, wherein the first integrated circuit die includes a first replica switch, wherein at least two terminals of the first replica switch are electrically connected to at least two corresponding terminals of one switch of the plurality of first switches or the plurality of second switches.

10. The apparatus of claim 9, wherein the first replica switch is smaller in size than the one switch to which its terminals are electrically connected.

11. The apparatus of claim 9, wherein the first replica switch is configured to sense a current flowing through the one switch to which its terminals are electrically connected.

12. The apparatus of claim 9, wherein the first replica switch is configured to detect a fault associated with the one switch to which its terminals are electrically connected.

13. The apparatus of claim 9, wherein the first integrated circuit die includes a second replica switch, wherein at least two terminals of the second replica switch are electrically connected to at least two corresponding terminals of another switch of the plurality of first switches or the plurality of second switches;
wherein the one switch and the another switch are of different sizes; and
wherein the first replica switch and the second replica switch are sized in proportion to the one switch and the another switch respectively.

14. The apparatus of claim 13, wherein the second replica switch is smaller than the another switch to which its terminals are electrically connected.

15. The apparatus of claim 13, wherein the second replica switch is configured to sense a current flowing through the another switch to which its terminals are electrically connected.

16. The apparatus of claim 13, wherein the second replica switch is configured to detect a fault associated with the another switch to which its terminals are electrically connected.

17. The apparatus of claim 1, wherein the first integrated circuit die electrically coupled to the lead frame using wire-bonding.

18. The apparatus of claim 1, wherein the second integrated circuit die electrically coupled to the lead frame using flip-chip bonding.

19. The apparatus of claim 1, wherein the plurality of first switches and the plurality of second switches each include one or more lateral double-diffused metal-oxide semiconductor field effect transistors.

20. The apparatus of claim 19, wherein the first integrated circuit die includes a through-silicon via configured to form an electrical connection to either drain terminals or source terminals of either the plurality of first switches or the plurality of second switches.

21. The apparatus of claim 20, wherein the through-silicon via is made using a single transfer layer process.

22. The apparatus of claim 19, the apparatus further comprising:
a fourth integrated circuit die electrically coupled to the lead frame;
wherein the fourth integrated circuit die includes a plurality of fifth switches and a plurality of sixth switches;
wherein the plurality of fifth switches and the plurality of sixth switches are interconnected with a plurality of third capacitors to form a third switched capacitor circuit, wherein the third switched capacitor circuit is configured to transition between at least two states in response to switching of the plurality of fifth switches and the plurality of sixth switches; and
wherein the controller circuit is electrically coupled to control switching of the plurality of fifth switches and the plurality of sixth switches; and
wherein the first integrated circuit die and the fourth integrated circuit die are vertically stacked.

23. The apparatus of claim 19, wherein the first integrated circuit die includes a plurality of metal clips coupled between at least two pairs of source and drain terminals of the plurality of first switches or the plurality of second switches.

24. The apparatus of claim 23, wherein the metal clips are copper clips that are soldered to the source and drain terminals.

25. The apparatus of claim 1, wherein the plurality of first switches and the plurality of second switches each include one or more vertical double-diffused metal-oxide semiconductor field effect transistors.

26. The apparatus of claim 25, wherein the first integrated circuit die includes a plurality of isolation trenches configured to electrically isolate the plurality of first switches and the plurality of second switches from each other.

27. The apparatus of claim 26, wherein the plurality of isolation trenches are formed using deep reactive ion etching.

28. The apparatus of claim 26, wherein an insulating layer is deposited in the plurality of isolation trenches.

29. The apparatus of claim 26, wherein a substrate of the first integrated circuit die is ground to reduce its thickness compared to a wafer from which the first integrated circuit die was made.

30. The apparatus of claim 25, wherein the first integrated circuit die includes a plurality of metal clips coupled between at least two pairs of source and drain terminals of the plurality of first switches or the plurality of second switches.

31. The apparatus of claim 30, wherein the metal clips are copper clips that are soldered to the source and drain terminals.

32. The apparatus of claim 1, wherein the plurality of first switches and the plurality of second switches are lateral double-diffused metal oxide semiconductor devices.
